(19) United States
(12) Patent Application Publication
(10) Pub. No.: US 2004/0105476 A1
(43) Pub. Date: Jun. 3, 2004

(54) Planar waveguide surface emitting laser and photonic integrated circuit

(76) Inventor: John G. Wasserbauer, Erie, CT (US)

Correspondence Address: INTELLECTUAL PROPERTY ADVISORS LLC, PO BOX 156, CANTON, CT, 06019, US

(21) Appl. No.: 10/643,355

(22) Filed: Aug. 19, 2003

Related U.S. Application Data
(60) Provisional application No. 60/404,350, filed on Aug. 19, 2002.

(51) Int. Cl. H01S 5/00; H01S 3/08

(52) U.S. Cl. 372/50; 372/96

(57) ABSTRACT

The present invention is a planar waveguide surface emitting laser (PWSEL) and photonic integrated circuit (PIC) technology. The PWVCL can stand alone or it can be integrated with a variety of optical devices, such as tuners, electro-optic or electro-absorption modulators (EOM or EAM), optical amplifiers (OA), waveguide or traveling wave photo detectors (WPD or TWPD), narrow or broadband filters, active or passive waveguides, and waveguide splitters or couplers to form photonic integrated circuits. Most or all of the components share the same transverse waveguide. A lateral index step or other suitable technique completes the waveguide so that light is guided in the longitudinal direction. Optical taps (reduced reflectivity mirrors) allow for surface emission of the light.

This application claims the benefit of U.S. Provisional Application No. 60/404,350, filed Aug. 19, 2002.

### BACKGROUND OF THE INVENTION

1. Field of the Invention

The present invention relates to designs, systems and methods of a semiconductor laser and, more particularly, to a planar waveguide surface emitting laser (PWSEL) and photonic integrated circuit (PIC) technology.

2. Description of the Related Art

It has been goal long since the creation of the semiconductor integrated circuit, and later after the creation of the semiconductor laser, to create a photonic, integrated circuit, whereby each device of the integrated circuit or chip uses photons in some way. To date enormous effort and investment has been expended in the pursuit of creating a photonic integrated circuit with mediocre results. Conventional opto-electronic systems utilize and are implemented with hybrid components selected specifically and individually to optimize interaction between devices and overall performance; only low levels of monolithic integration have been achieved. For example, the highest level of integration in commercially available opto-electronic circuits is four devices: a laser, a modulator, an amplifier and a power monitor to achieve suitable performance. Greater levels of integration have been achieved, but at the expense of individual device performance, typically reducing the overall opto-electronic circuit performance to the lowest common denominator.

There are numerous obstacles to overcome in the state of the art. In many ways photons appear to be more “fragile” than electrons, that is, more easily perturbed, absorbed or scattered. Photons, unlike electrons, have proven much more difficult than first imagined to generate, process and collect in integrated circuit designs. Furthermore, each step of generating, processing and collecting photons requires a highly specialized device structure that generally differs significantly from other process. For example, device architectures and fabrication processes for generating photons are significantly different than those for collecting photons. Such differences increase the complexity of the epitaxial growth and fabrication steps required for integration enormously. Moreover, no single materials system has been found to generate all the wavelengths of light of interest, or in some cases, all the elements required to make a high-performance device. This has led to such technologies as metamorphic growth and wafer fusion techniques.

In addition to purely photonic integration, it has proven difficult to integrate photonic devices on the same substrate as the high performance electronic devices required to drive them. This has led to such technologies as the growth of GaAs on Si. To date none of these technologies has produced an integrated device with performance that rivals its hybrid counterpart. In view of such disadvantages, purely photonic and photonic/electronic integrated circuits have found little commercial success outside the laboratory.

As a result of the disadvantages in the prior art, there is a long-felt need in integration technology for a design to integrate purely photonic devices whereby such devices share a common set of design elements. Commercial success can be reached if such integration technology operates at the telecommunications wavelengths, for example, 1.3 μm and or 1.55 μm. As for individual devices, probably the most difficult and complex device to fabricate is the semiconductor laser. In the following discussion we will describe in detail the current state of the art, its advantages and disadvantages.

The edge-emitting laser operates at wavelengths of 1.3 and 1.55 μm and is currently the telecommunications industry standard. In its simplest design, the edge-emitting laser, called the Fabry-Perot (FP) laser—although not spectrally pure—has been sufficient to reach short distances at the fiber dispersion minimum of 1.3 μm. Longer distances and or higher speeds require a different edge-emitting laser—the distributed feedback (DFB) laser, which is spectrally pure. In comparison, FP lasers are much cheaper to produce than DFB lasers. However, both FP and DFB lasers have disadvantages, generally in the areas of high test and assembly costs, mainly due to the necessity of cleaving the crystal to form facets prior to testing and burn-in, which are the industry standard used to eliminate unsuitable or unreliable lasers in the manufacturing process. Finally, edge-emitting lasers have further disadvantages inherent in the emitted elliptical output beam, which reduces the coupling efficiency into a fiber and typically requires external optics to correct for asymmetry problems.

Vertical cavity surface emitting lasers (VCSELS) are relatively inexpensive to fabricate as opposed to edge-emitting lasers primarily due to factors such as the planar nature of the facets, the circular output beam and the wafer-level testability. VCSELs also are cheaper to assemble due the relative ease of alignment and the simplicity of the external optics. Conventional VCSELs, however, have disadvantages including limited output power and significant chirp. As a result there is a need for a surface emitting laser matching or approaching the performance of the DFB laser in the long-wavelength (LW) spectral range, for example, between 1.3 to 1.6 μm. Such a laser must have a significant cost and/or performance advantage, including spectral purity, chirp, power, speed, and reliability.

### SUMMARY OF INVENTION

The present invention is a planar waveguide surface emitting laser (PWSEL) and or photonic integrated circuit (PIC) technology. The PWSEL can be a stand alone device or integrated with other forms of optical devices to form photonic integrated circuits such as, for example, tuners, electro-optic or electro-absorption modulators, optical amplifiers, photo detectors, narrow or broadband filters, active or passive waveguides, and waveguide splitters or couplers. Most or all of the components share the same vertical and lateral optical confinement, so as to guide light along a longitudinal axis or the longitudinal direction. The photonic integrated circuits or other devices made with utilizing the teachings of the present invention can be provided with optical taps and or reduced reflectivity mirrors to allow for surface emission of the light.

The present invention provides a laser having optical confinement and feedback provided by a pair of distributed Bragg reflector mirrors surrounding a cavity in the vertical (y) direction, a waveguide in the lateral (x) direction, and a distributed feedback grating in the longitudinal (z) direction. Alternatively, the present invention provides a laser having optical confinement and feedback provided by a pair of distributed Bragg reflector mirrors surrounding a cavity in the vertical (y) direction, and a distributed feedback grating in the radial (r) direction. The laser can extract useful light using an optical tap, etched or cleaved facet. Optical confinement is achieved using gain/loss modulation, index modulation, effective index modulation, and/or resonant wavelength modulation. Numerous devices necessary for creating a photonic integrated circuit are accomplished by the present invention.

### BRIEF DESCRIPTION OF THE DRAWINGS

In the drawings, like numerals describe like components throughout the several views:

FIG. 1 is a schematic view illustrating a generic electro-absorption-modulated, amplified, DFB laser;

FIG. 2 is a side cross-sectional view illustrating an optically pumped VCL structure;

FIG. 3 is a side cross-sectional view illustrating an external feedback VCL structure with a diffraction grating;

FIGS. 4(a), 4(b) and 4(c) are schematic views illustrating waveguides having optical feedback according to cleaved or etched facet structure as shown in FIG. 4(a), distributed Bragg reflector structure as shown in FIG. 4(b), or distributed feedback structure as shown in FIG. 4(c);

FIGS. 5(a) and 5(b) illustrate comparisons between vertical mode profiles of an in-plane laser as shown in FIG. 5(a) and a vertical cavity laser as shown in FIG. 5(b), respectively;

FIG. 6 is a side cross-sectional view illustrating a waveguide according to the present invention with effective cladding confinement in the vertical direction and index modulation confinement using epitaxially regrowth in the lateral direction;

FIG. 7 is a side cross-sectional view illustrating a waveguide according to the present invention with effective cladding confinement in the vertical direction and effective index using modulation confinement iridge waveguide formation in the lateral direction;

FIG. 8 is a side cross-sectional view illustrating a waveguide according to the present invention with effective cladding confinement utilizing a semiconductor bottom mirror and dielectric top mirror in the vertical direction, whereby lateral optical confinement is provided by resonant wavelength modulation in the lateral direction;

FIG. 9 is an end, cross-sectional view illustrating a waveguide according to the present invention with effective cladding confinement via a semiconductor bottom mirror and metamorphic top mirror in the vertical direction, whereby lateral optical confinement is provided by resonant wavelength modulation in the lateral direction;

FIGS. 10(a) and 10(b) are schematic views illustrating exemplary embodiments of waveguide gratings using vertical thickness corrugation as shown in FIG. 10(a), and lateral width corrugation as shown in FIG. 10(b);

FIGS. 11(a) and 11(b) are side cross-sectional views illustrating an exemplary waveguide with grating and optical tap placed at an optical standing wave peak as shown in FIG. 11(a), and an optical standing wave null as shown in FIG. 11(b);

FIGS. 12(a), 12(b) and 12(c) are side cross-sectional views illustrating an exemplary waveguide with grating and optical tap with various output layers and tapers, whereby a homogeneous output coupling layer with lens-like taper is shown in FIG. 12(a), a DBR output coupling layers with linear taper is shown in FIG. 12(b), and a DBR with cavity output coupling layers having a reverse linear taper is shown in FIG. 12(c);

FIGS. 13(a) and 13(b) are top cross-sectional views illustrating an exemplary waveguide and optical tap with various tapers, whereby a homogeneous output coupling layer with lens-like taper is shown in FIG. 13(a), and a DBR output coupling layers with linear taper is shown in FIG. 13(b);

FIG. 14 is a side cross-sectional view illustrating an exemplary PWVCL;

FIGS. 15(a), 15(b) and 15(c) illustrate a standing wave profile for gratings with cavities of a diameter of ¼-λ as shown in FIG. 15(a), a diameter of ½-λ as shown in FIG. 15(b), and a diameter of 1-λ as shown in FIG. 15(c);

FIG. 16 is a top view illustrating an exemplary PWVCL with radial grating pattern, whereby a cross-sectional index and standing wave profile are shown in the top of FIG. 16;

FIG. 17 is a top view illustrating the contact and mesa layout for an exemplary 4-lobed PWVCL;

FIGS. 18(a) and 18(b) are top and side cross-sectional views, respectively, illustrating an exemplary linear waveguide PWVCL with intracavity modulator;

FIGS. 19(a), 19(b) and 19(c) are top views illustrating an exemplary waveguide combiners and splitters, whereby FIG. 19(a) is a Y-combiner, FIG. 19(b) is a Y-splitter, and FIG. 19(c) is a sequential combiner;

FIG. 20 is a top view illustrating an exemplary coupled waveguide configured to operate as a splitter;

FIG. 21 is a top view illustrating an exemplary grating assisted co-directional coupler configured to operate as a switch;

FIG. 22 is a side cross-sectional view illustrating an exemplary switch between active and passive waveguides using a grating assisted co-directional coupler (GACC), whereby vertical confinement in the passive waveguide is formed by bulk cladding of lower index;

FIG. 23 is a side cross-sectional view illustrating an exemplary switch between active and passive waveguides using a grating assisted co-directional coupler (GACC). Vertical confinement in the passive waveguide is formed via effective index cladding of lower index;

FIG. 24 is a side cross-sectional view illustrating an exemplary grating filter;

FIG. 25 is a side cross-sectional view illustrating an exemplary extended tuning range filter;

FIG. 26 is a schematic view illustrating the separate comb functions of the sampled gratings in an extended tuning range filter;

FIG. 27 is a top view illustrating an exemplary resonant ring filter;

FIG. 28 is a top view illustrating an exemplary guide/anti-guide modulator;

FIG. 29 is a top view illustrating an exemplary tunable PWVCL;

FIG. 30 is a top view illustrating an exemplary resonant cavity detector;

FIG. 31 is a side view illustrating an exemplary configuration equally applicable for Vertical Cavity Laser or an Electro-optic or Electro-absorption Modulators or an amplifier with partial out-of-plane, external integration;

FIG. 32 is a side view illustrating an exemplary configuration equally applicable for Vertical Cavity Laser or an Electro-optic or Electro-absorption Modulators or an amplifier with partial out-of-plane, monolithic integration;

FIG. 33 is a side view illustrating an alternate exemplary configuration equally applicable for Vertical Cavity Laser or an Electro-optic or Electro-absorption Modulators or an amplifier with partial out-of-plane, monolithic integration;

FIG. 34 is a top view illustrating a contact and mesa layout for an exemplary configuration equally applicable for a 2-lobed, or bow-tie PWVCL with intracavity modulator;

FIG. 35 is a side view illustrating an exemplary configuration equally applicable for an integrated photodetector or PWVCL or an Electro-optic or Electro-absorption Modulators or an amplifier;

FIG. 36 is a top view illustrating an exemplary configuration equally applicable for an integrated filter or amplifier or photodetector;

FIG. 37 is a top view illustrating an exemplary wavelength division multiplexed laser array;

FIG. 38 is a top view illustrating an exemplary wavelength division de-multiplexed detector array;

FIG. 39 is a top view illustrating an exemplary optical add-drop multiplexer;

FIG. 40 is a top view illustrating an exemplary dynamic equalizer;

FIG. 41 is a side view illustrating an exemplary configuration equally applicable for an optically pumped, integrated PWVCL or an Electro-optic or Electro-absorption Modulators or an amplifier; and

FIG. 42 is a flow diagram illustrating the method of fabrication for an effective index waveguide.

### DESCRIPTION OF THE EMBODIMENTS

In the following detailed description, reference is made to the accompanying drawings, which form a part hereof, and in which is shown by way of illustration specific embodiments in which the invention can be practiced. These embodiments are described in sufficient detail to enable those skilled in the art to practice the invention, and it is to be understood that other embodiments can be utilized and that structural changes can be made without departing from the spirit and scope of the present invention. Therefore, the following detailed description is not to be taken in a limiting sense, and the scope of the present invention is defined by the appended claims.

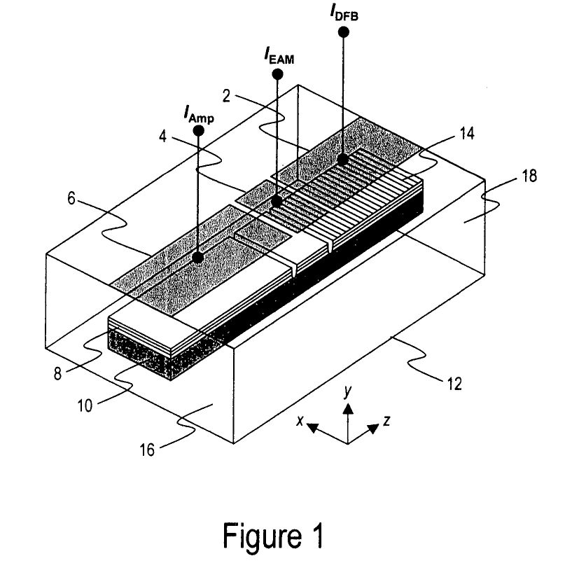

Currently, the laser source that is best suited for long-wavelength telecommunication applications is an electro-absorption modulated, amplified DFB laser 1, as shown in FIG. 1. The structure consists typically of a DFB section 2 coupled to a modulator 4 section and an amplifier 6 section. The DFB 2, and the modulator and amplifier sections 4 and 6, respectively, share a common active area 8 and waveguide 10, surrounded by a cladding 12. Distributed feedback can be achieved through a first-order grating 14 formed adjacent the active area. Separate electrodes can be used to bias independently the DFB 2, and the modulator and amplifier sections 4 and 6, respectively. In operation, the DFB section 2 is forward biased under DC conditions. Lasing is generated in the DFB section 2 and a fraction of the light is coupled into the modulator 4. The modulator 4 and the amplifier 6 sections are formed so as to be relatively transparent at the lasing wavelength. If the modulator 4 is reverse biased, the absorption band edge shifts, thereby increasing the attenuation and blocking light from entering the amplifier 6. Additionally, as modulated light enters the amplifier 6 the light is amplified and emitted from a front facet 16. The front facet 16 can be coated with an anti-reflection (AR) coating as is conventionally known to reduce reflections that diminish the performance of the device. A back facet 18 can be formed on an alternative surface and can be advantageously a high-reflectivity (HR) coating for greater efficiency. The principal performance advantages of the electro-absorption modulated (EAM), amplified, DFB laser are high output power due to the long cavity, narrow line width due to the distributed feedback, and low chirp due to the external-cavity light modulation.

Conventional VCLs have two significant drawbacks with respect to EAM-DFB lasers: (1) they generate significantly less single mode power and (2) have significantly more chirp defined as a variation of lasing wavelength under modulation. Reduction in power limits the transmission distance that can be obtained due to fiber attenuation. Chirp limits the transmission distance that can be obtained due to fiber dispersion.

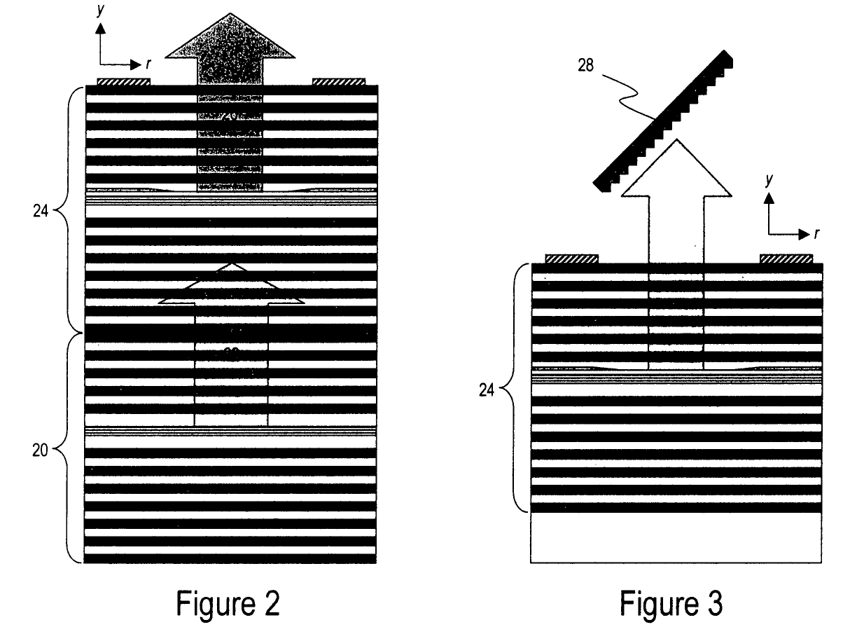

Referring now to FIG. 2, an optically pumped VCL structure with or without external feedback has been proposed to address conventional problems associated with reduced power and chirp. The optical pumping structure includes a shorter wavelength laser 20 and a longer wavelength laser 24 pumped either from the side (not shown) or below with the shorter wavelength laser 20. The shorter wavelength photons 22 generate electron-hole pairs that recombine to emit photons at a longer wavelength 26. A hybrid assembly method should be used when the shorter wavelength laser 20 is pumped from the side. If the shorter wavelength laser 20 is pumped from the bottom, then a hybrid assembly, wafer fusion, or monolithic epitaxial method can be used to couple the two lasers. The disadvantage to the optical pumping approach is in the need for one of the hybrid assembly, wafer fusion, or monolithic epitaxial methods in order to couple the first laser to the second. Each of the hybrid assembly, wafer fusion, or monolithic epitaxial methods, all of which are complex, have disadvantages including reliability issues and relatively low yield in the manufacture thereof.

Referring to FIG. 3, an external feedback VCL structure has been proposed to address conventional problems associated with reduced power and chirp. In this structure a mode selective element, such as a curved mirror, a grating 28 or, alternatively an additional DBR, is used to provide additional loss for the undesired, higher order modes, thus suppressing lasing in those modes. As a result, a much larger device can be made and significantly greater output power achieved theoretically. One disadvantage of the external feedback VCL structure is the decreased photon density as the device size increases, thereby limiting the modulation speed of the device. An additional disadvantage in larger devices includes the larger parasitic capacitance, which also limits the modulation speed of the device. Finally, depending on the specific implementation, a significant disadvantage exists in integrating the external mode-selective element, which requires expensive alignment in manufacturing, thereby increasing the total cost of the device.

Two other methods have been proposed to achieve the advantages of surface emission for in-plane lasers without the known disadvantages of VCSELs. An etching method involves etching two mirrors at the output facet of the device. One mirror is oriented 90° (90° mirror) to the direction of the in-plane waveguide and the other mirror is oriented 45° (45° mirror). The 90° mirror provides the feedback necessary to achieve lasing threshold and the 45° mirror reflects the output light such that it exits normal to the surface. Disadvantages to the first etching method include problems in the fabrication of etched mirrors. The 45° mirror and 90° mirror not only need to be precisely positioned at either 45 or 90°, but the 45° mirror and 90° mirror must be manufactured extremely smooth and extremely flat (low curvature), thereby increasing the control required in the manufacturing and increasing the total cost of the device. If the 45° mirror and the 90° mirror are not manufactured extremely smooth and or extremely flat, then losses in the device occur due to misalignment, curvature or scattering resulting in higher threshold, reduced efficiency, and lower output power of the device.

Another etching method involves etching a second-order diffraction grating into the output area of an etched facet laser. The second-order diffraction grating creates a significant amount of surface normal scattering that can be collected as the output of the laser. Disadvantages to the second etching method include complex manufacture. In the manufacturing process, the cladding and contact layers are removed from the waveguide in order to avoid excessive absorption of the output light, thereby including and or necessitating a complicated etch process and the formation of an etched facet. Another problem in the second etching method is that light exiting an etched facet creates a curved wave front. As a result, the grating must be curved to compensate and focus the light in at least one dimension. Curved gratings are produced by lithography requiring an additional critical alignment step, whereby gratings produced by holography lack the alignment step. Finally, the second etching method having a second order grating scatters only a fraction of the light possible, thereby limiting the maximum efficiency of the laser.

The disadvantages to the many approaches to photonic integration and laser fabrication result in poorer performance and or higher cost relative to the EAM-DFB approach. Nevertheless, other disadvantages of the EAM-DFB structure remain to be overcome including manufacturing complexity, cost of production, limited integrateability, and required external optics. The present invention overcomes the disadvantages in the art to provide a novel laser structure that solves many of the problems associated with the current state of the art, but also enables unprecedented ease of photonic integration. Subsets of the laser device structure can be selected to create a variety of optical devices, such as tuners, combiners, splitter, mixers, switches, active or passive waveguides, narrow or broadband filters, electro-optic or electro-absorption modulators, amplifiers and photo detectors. In short, all the functions of a photonic circuit can be integrated more easily due to the commonality of structural elements that make up each device.

### Laser Embodiments

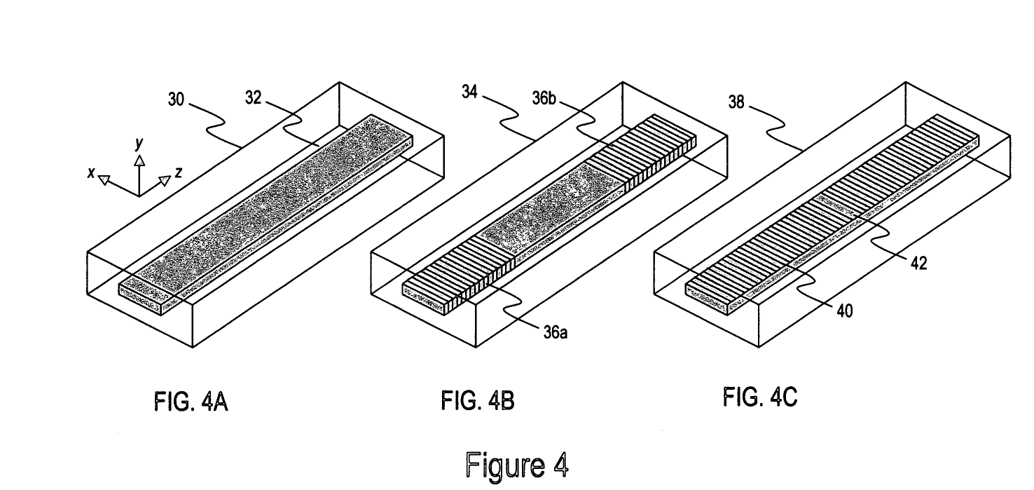

Referring to FIG. 4(a), a laser 30 in its simplest form requires a gain medium 32 disposed between two mirrors to form a cavity, whereby the medium 32 provides gain and the mirrors provide the feedback necessary for stimulated amplification of light. In order to improve the threshold and efficiency of any of laser, light is concentrated on a path normal to the mirrors within a waveguide formed from a core 32 and a cladding 30. The waveguide 30, 32 confines the light in the x (lateral) and y (vertical) directions, while the light is allowed to propagate along the z (longitudinal) direction. A distributed Bragg reflector (DBR) laser structure 34 is illustrated in FIG. 4(b). The mirrors 36a and 36b, so-called distributed Bragg reflectors (DBRs), are composed of alternating layers of high and low index material whose thickness d meets the Bragg condition (d=λ/4). Referring to FIG. 4(c) a distributed feedback (DFB) laser structure 38 is disclosed where the feedback is placed inside the cavity utilizing a corrugation in the active layer, a so-called grating 40, whereby the feedback is distributed along the length of the cavity. As a result, the laser 38 can operate solely on distributed feedback when a design having a robust grating or an extended cavity is used because the reflectivity of the laser facets become insignificant (except for their phase contributions).

Both DBR and DFB lasers are of interest commercially because they provide wavelength selectivity and are usually designed for single mode operation, for example, only one wavelength propagates between the mirrors or along the cavity. Typically, the DBR laser structure 34 is composed of materials having an index contrast higher than produced by the corrugation of a diffraction grating, whereby the DBR laser structure 34 reflects a broader range of wavelengths than the DFB laser structure 38. In order to select a single wavelength, a 1-λ cavity is placed between the mirrors 36a and 36b of the DBR laser structure 34. Additionally, as the DFB grating 40 has lower index contrast, it can reflect a narrow band of wavelengths, resulting in the DFB laser structure 38 requiring no cavity length beyond the regular periodicity of the grating to select a single mode. In effect the cavity length is ¼λ and is equal to ½ of a grating period. Adding a ¼-wave shift to the grating 42, creating a cavity length of ½λ, as shown in FIG. 4(c) can significantly reduce the threshold resulting in the laser operating at the Bragg wavelength and the peak in the standing wave pattern then coincides with the location of the grating shift 42. The grating shift 42 advantageously can be used to adjust the power delivered at an output facet by shifting the peak power point to the output facet. Also, the optical intensity can be spread throughout the cavity to avoid spatial hole burning by distributing the ¼-wave shift over length of the cavity.

As is shown in the laser designs of FIG. 4, the waveguide can be utilized to provide wavelength selectivity in the x and y dimensions, and utilized for single mode operation. FIG. 4(a) illustrates a conventional rectangular waveguide 32. It consists of a core 32 of high refractive index n₁ enclosed by or otherwise encased in a cladding a material 30 of lower refractive index n₂. In operation, light travels in both the core and the cladding and the optical mode “sees” both core and cladding simultaneously. Light traveling in the optical mode moves through the waveguide as if it were moving through a homogeneous material of refractive index n_{eff}, where n₂<n_{eff}<n₁ so as to determine the shape of the optical mode. When n₂>n_{eff}, the solution to the wave equation is sinusoidal (propagating) and when n₁<n_{eff}, the solution is evanescent (exponentially decaying).

Selection of appropriate materials and refractive index can be used to determine where and how to terminate an optical standing wave at the waveguide boundary conditions. The laser emission wavelength, λ, is determined by the wavelength of the light along the three axes of the laser and is given by the wave number, k,

k²=kₓ²+k_{y}²+k_{z}², Equation 1

where k=2π/λ is the wave number. If the structure is radially symmetric, the equation becomes,

k²=k_{y}²+2kᵣ², Equation 2

where kᵣ=kₓ=k_{z}. In most lasers, light is guided in two dimensions by the waveguide, and bounces between the mirrors in the third dimension. Thus, the wavelength in the x and y directions is determined by the waveguide, while in the z direction it is either determined by the cavity length, in the case of DBR mirrors, or the DFB in the cavity itself. Note that the overall lasing wavelength is determined largely by the shortest wavelength in the structure, which is usually λ_{y}.

For example, assuming that a lasing wavelength of 1550 run is desired then the DFB grating will have a wavelength Λ of 4 μm so that a grating of ¼Λ=1 μm segments of high and low index. The lateral waveguide shall be 6 μm wide for single mode operation, yielding an approximate lateral wavelength of 24 μm. From Equation 1, we calculate the vertical optical cavity length as

$$\begin{matrix}{λ}_{y} = {( \frac{1}{{1550}^{2}} - \frac{1}{{4000}^{2}} - \frac{1}{{24000}^{2}} )}^{- 1 / 2} \\ = 1685.5 nm .\end{matrix}$$

Advantageously, the laser structure of the present invention, unlike conventional DBR and DFB lasers, employs DBR and/or DFB mirrors in two or three dimensions, whereby if the number of dimensions is two the waveguide is used to select the wavelength in the third dimension.

### Waveguides

Lasing action has two important requirements: optical confinement (also known as the concentration of light), and optical feedback (the in-phase reflection of light). Conventionally optical confinement is achieved through the formation of a waveguide, whereas optical feedback is achieved through the formation of a mirror. Since there are only three axes along which light can travel, the requirements of optical confinement and or feedback need to be present in all three dimensions. Throughout this specification dimensions will be referenced as lateral (x-direction), vertical (y-direction), and longitudinal (z-direction). Forming a waveguide requires confinement of the light in at least two dimensions, typically the vertical and lateral, and having the light travel in the third dimension, typically the longitudinal.

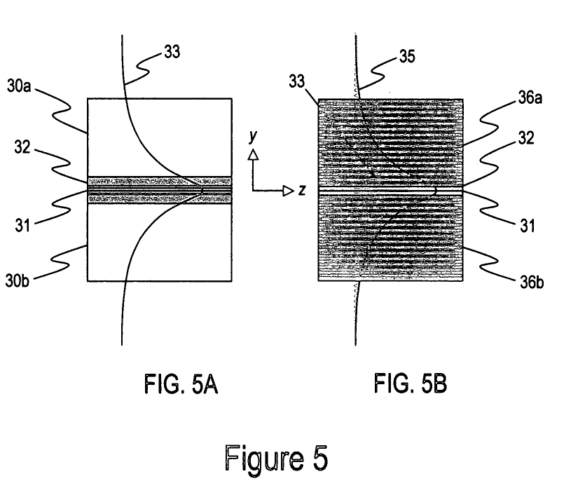

Referring to FIG. 5(a), an edge-emitting laser of a vertical layer design having cladding layers 30a and 30b, a gain medium 31 and a core structure 32 also referred to as a graded index (GRIN) structure. Vertical confinement of the electromagnetic field is achieved by placing a layer or layers of elevated refractive index, n₂, in between layers of reduced refractive index, n₁. The edge-emitting laser of this vertical layer design has cladding layers 30a and 30b, a core structure 32 also referred to as a graded index (GRIN) structure, and a gain medium 31. A vertical mode profile 33 peaks at the center, where the index is highest, and decreases exponentially in the cladding layers. Similarly, referring to FIG. 5(b), a DBR laser structure can be used to create effective cladding layers using partial reflection of vertically propagating waves. In this embodiment the core structure 32 is comprised of a 1-λ cavity surrounding a gain medium 31, and is sandwiched between two DBR mirrors 36a and 36b. The vertically counter propagating waves create a standing wave pattern 33 whose envelope function 35 is peaked in the cavity layers and decreases exponentially with distance into the DBR mirrors 36a and 36b. The layers in either structure can be formed from a variety of materials and by a variety of methods, some of examples of which will be described later. In the following discussion of lateral optical confinement, it will be assumed that the vertical confinement is provided by effective cladding layers composed of DBR mirrors 36a and 36b.

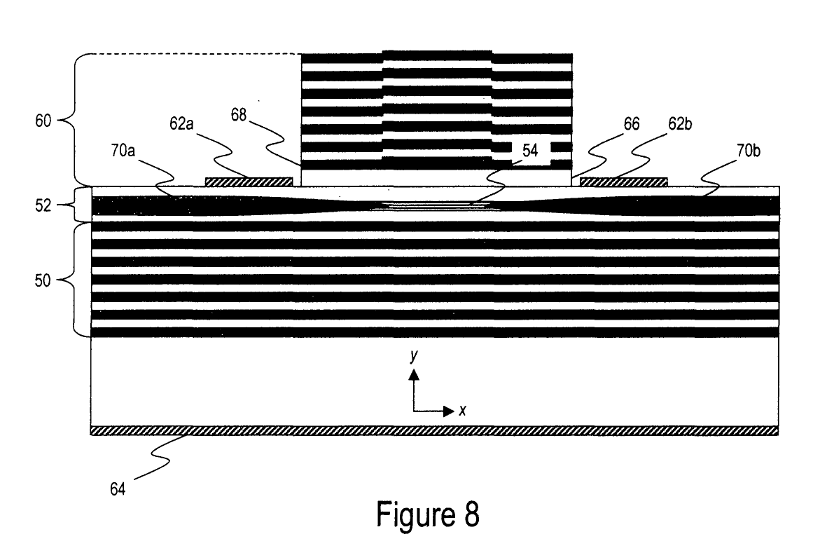

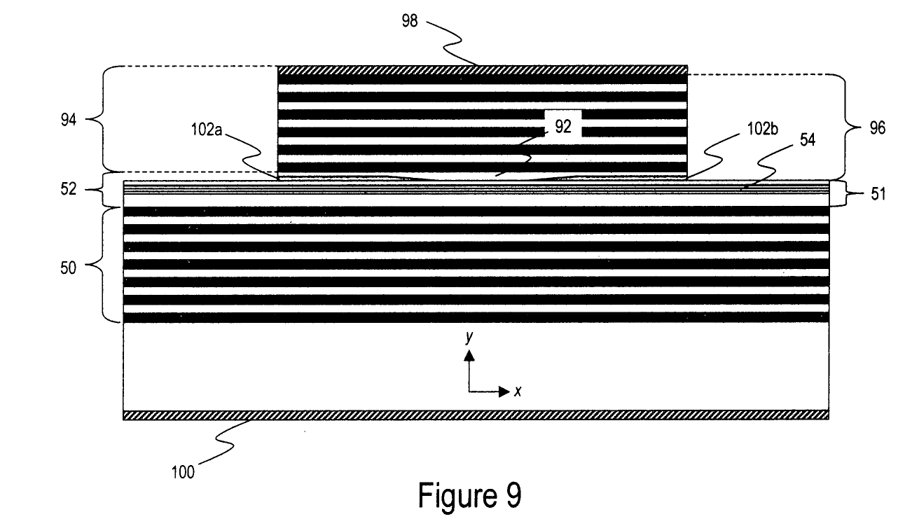

Various approaches can be utilized to create lateral optical confinement, with the approaches generally falling into two broad categories: modulation of gain and loss, and index modulation. In gain/loss modulation, the imaginary part of the refractive index is tailored laterally so as to provide more gain or less loss for the fundamental mode with respect to higher order modes. An example of gain modulation is the use of a current constriction element such as, for example, an oxide or implant aperture to pump the fundamental mode. Exemplary embodiments of implant and oxide apertures appear in FIGS. 8 and 9, respectively, both of these techniques provide current confinement as well as gain modulation. This is an important and advantageous function of the present invention in the embodiment of diode lasers as the efficiency of the device depends on the overlap between the optical mode and electrical carrier profiles.

Similarly, there are a variety of methods that can be used to provide loss modulation. For example, anti-phasing of a mirror can be used to increase transmission losses for higher order modes to provide selective loss modulation. Further, the optical cavity can be extended to increase diffraction losses for higher order modes, or selective mirror doping can be used to increase absorption losses for higher order modes. Both gain and loss modulation are more effective with some degree of index modulation.

Index modulation techniques, by contrast, tailor the real part of the refractive index laterally so as to form a waveguide. Methods of index modulation include lateral regrowth of lower index material, rib or ridge waveguide formation, oxide apertures, and effective index guiding via resonant cavity wavelength modulation. To form a waveguide using the index modulation methods requires forming a region of higher index surrounded by a region of lower index. The relative index step determines the width and height of the waveguide for single mode operation, a typical design criterion for communications applications. In the design of lateral index profiles, it is important to keep in mind that the greater the index step between the effective indexes of refraction, the smaller the single mode cutoff dimensions.

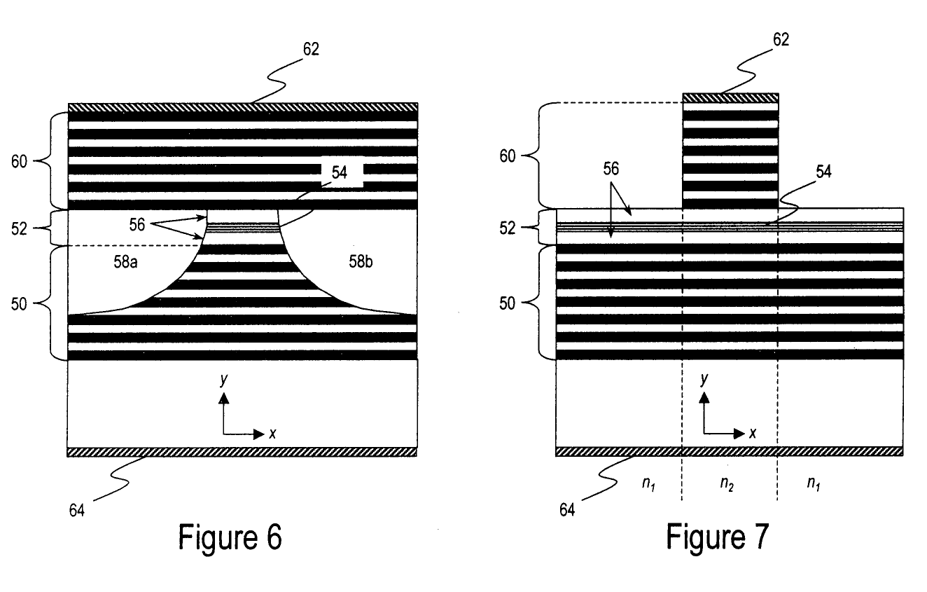

An exemplary embodiment of the index modulation technique is illustrated in FIG. 6, which shows an end view cross section of an epitaxially regrown waveguide. In this structure a bottom, electrically conductive mirror 50 is formed on a substrate. A 1-λ cavity 52 including multi-quantum well (MQW) active layers 54 surrounded by cavity layers 56 is formed on the bottom mirror. A mesa is then patterned and etched into this structure using standard planar fabrication techniques. An epitaxial growth technique, such as metal organic chemical vapor deposition (MOCVD) or liquid phase epitaxy (LPE), is used to selectively replace the etched material with cladding material 58, which is a method used to produce buried heterostructure lasers. A second, non-selective regrowth can be used to add a top, electrically conductive mirror 60 and/or contact layer to the structure. Top 62 and bottom 64 electrodes are disposed on upper and lower surfaces of the device. Lateral current confinement is achieved by selecting an appropriate material, such as semi-insulating InP, for the first regrowth. In summary, vertical optical confinement is achieved via the effective cladding method (top and bottom DBR mirrors), while lateral optical confinement is achieved through the index modulation method (material of higher index surrounded by material of lower index).

An exemplary embodiment of the effective index modulation technique is illustrated in FIG. 7, which shows an end view cross section of a ridge waveguide. In this structure a bottom, electrically conductive mirror 50 is formed on a substrate. A 1-λ cavity 52 including MQW active layers 54 surrounded by cavity layers 56 is formed on the bottom mirror. A top, electrically conductive mirror 60 is formed on the cavity 52. A top electrode 62, consisting of a metal contact, is formed on the top mirror and patterned in the shape of a waveguide. The top contact can be used to increase the reflectivity of the upper mirror as well as for current injection. Using the metal as a self-aligning mask, the top mirror layers are etched down to near the 1-λ cavity 52, using a standard etch technique as is known in the art. A bottom electrode 64 is formed on the bottom surface of the substrate. The etched surface and/or the sides of the ridge can be passivated with a dielectric material (not shown). Formation of the ridge defines two vertical cross sections of the device: the core, with effective index n2, and the cladding, with effective index n1. The optical field penetrates the cladding layer to the etched surface where a lower index of refraction material is present, typically either air or dielectric. Since the refractive index of air or dielectric is much lower than that of the DBR mirror, n2>n1, thereby producing lateral optical confinement. Lateral current confinement is achieved by proximity current injection from the laterally restricted ridge. In summary, vertical optical confinement is achieved via the effective cladding method (top and bottom DBR mirrors), while lateral optical confinement is achieved through the effective index modulation method (material of higher index surrounded by material of lower index).

The effective index technique can be applied to resonant cavities, such as those found in a VCL. For clarity, we will refer to this as resonant wavelength modulation. When the wave equation is separable into horizontal and vertical solutions, Hadley showed that, for the vertical mode,

$$\frac{Δ {n}_{eff}}{{n}_{eff}} = \frac{Δ λ}{λ} \qquad Equation 3$$

where neff is the vertical effective index and X is the vertical resonant wavelength. Thus, by modifying the wavelength of the vertical cavity in the lateral direction, it is possible to create an effective index difference between the core and cladding. In the above equation Δneff is the effective index step from the core to the cladding and is give as Δneff=ncladding−ncore. Similarly Δλ=λcladding−λcore. The sign of the effective index step can be negative, which produces a waveguide, or positive, which produces an antiguide. From Equation 3 only 1-2 nm of wavelength difference is sufficient to form the waveguide. This can be achieved by creating a thin step (5-10 nm) near the active area, or a thicker one farther from the active area, whereby the thickness of the step can be calculated numerically.

An exemplary embodiment of the resonant wavelength modulation technique is illustrated in FIG. 8. In this structure a bottom, electrically conductive mirror 50 is formed on a substrate. A 1-λ cavity 52 comprised of MQW 54 surrounded by cavity layers is formed on the bottom mirror. A top, dielectric mirror 60 is formed on the cavity 42. A ½-λ phasing layer 66 is used to ensure correct phasing of the mirror. A rib is formed in the first ¼ wave layer 68 of the mirror such that the layer is slightly thinner on either side of the intended waveguide. Top electrodes 62, are formed on the cavity. A bottom electrode 64 is formed on the bottom surface of the substrate. The rib defines two vertical cross sections of the device: the core, with resonant wavelength λ2, and the cladding, with resonant wavelength λ1, where λ2>λ1. From Equation 3, this results in lateral optical confinement. Lateral current confinement is achieved by ion implantation 70. In summary, vertical optical confinement is achieved via the effective cladding method (top and bottom DBR mirrors), while lateral optical confinement is achieved through the resonant wavelength modulation method (a DBR of higher wavelength surrounded by a DBR of lower wavelength). The advantages of this embodiment include epitaxial simplicity and ease of fabrication. This structure involves only a single, monolithic growth including only one mirror. Furthermore, all of the waveguides are formed in dielectric, removing the need for complex etching and oxidation procedures.

An alternative embodiment of the resonant wavelength modulation technique is illustrated in FIG. 9. In this structure a bottom, electrically conductive, InP/InGaAlAs mirror 50 is formed on an InP substrate. A partial, ¾-λ cavity 51 including MQW active layers 54 is formed on the bottom mirror 50. A thin, oxidation layer 102 composed of high-Al-content AlGaAs is formed adjacent to the partial cavity 51. A ¼-λ metamorphic GaAs layer 92 is disposed adjacent the partial cavity 51 forming a 1-λ hybrid cavity 52. The metamorphic layer interface is placed at a null in the optical field so as to minimize scattering and absorption losses due to defects. Additional layers of thickness equal to an integer multiple of ½-λ can be inserted above or below the metamorphic interface without changing the location of the null. A top, metamorphic, electrically conductive, GaAs/AlGaAs DBR mirror 94 is disposed adjacent to the hybrid cavity 52. The oxidizing layer, hybrid cavity layer and DBR can be grown monolithically 96. Alternatively, if the substrate, bottom DBR, and cavity are composed of lattice-matched GaAs/AlGaAs, then the oxide layer, hybrid cavity layer and DBR 96 can also be lattice-matched and the entire structure can be grown monolithically. A top electrode 98, consisting of a metal contact, is formed on the top mirror and patterned in the shape of a waveguide. The top contact can be used to increase the reflectivity of the upper mirror as well as for current injection. Using the metal 98 as a self-aligning mask, the top mirror 96 layers are etched down to just past the oxidation layer 102, using a standard etch technique as is known in the art. The structure is placed into an oxidizing environment and the high-Al-content layer 102 oxidizes laterally inward until the desired waveguide width is achieved. A bottom electrode 64 is formed on the bottom surface of the substrate. The oxide layer defines two vertical cross sections of the device: the core, with resonant wavelength λ2, and the cladding, with resonant wavelength λ1, where λ2>λ1. From Equation 3, this results in lateral optical confinement. Lateral current confinement is achieved via the same oxide layers 102. In summary, vertical optical confinement is achieved via the effective cladding method (top and bottom DBR mirrors), while lateral optical confinement is achieved through the resonant wavelength modulation method (a DBR of higher wavelength surrounded by a DBR of lower wavelength). The advantages of this embodiment include the lower resistance and more uniform current injection that can be achieved. Since the top and bottom contacts cover the entire mirror, the majority of the current flow is vertical.

### Gratings

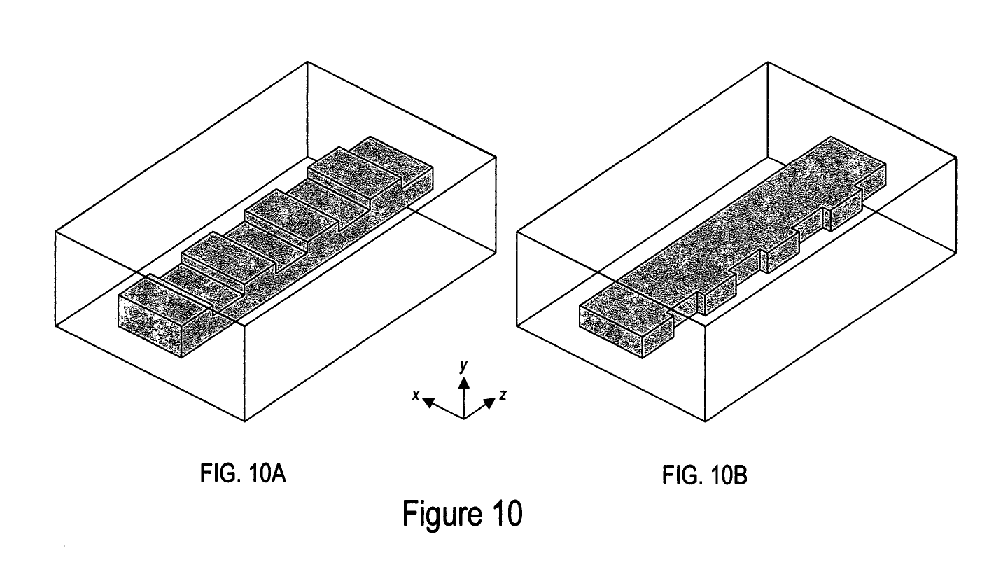

Another important element of this invention is the distributed feedback (DFB) grating. A grating consists of a periodic perturbation in the characteristic phase, β, of the waveguide, which is given by,

$$β = \frac{2 π {n}_{eff}}{λ} \qquad Equation 4$$

where neff is the effective refractive index of the waveguide. The perturbation usually takes the form of a vertical or lateral corrugation, which changes the thickness of the layer in either the x or y dimension. Thus, as the light wave propagates down the z direction, it sees a periodic change in the effective refractive index, causing a certain amount of reflection from each phase discontinuity. FIG. 10 gives examples of vertical and lateral corrugations in a waveguide. If the corrugations are in the shape of a square wave, then each uniform section of the grating has an effective index n1 or n2. As the longitudinal wave travels from material of index n2 to material of index n1 and back again, the reflection, r, at each interface can be calculated as,

$$r = \frac{{n}_{2} - {n}_{1}}{{n}_{2} + {n}_{1}} . \qquad Equation 5$$

Grating formation follows the same prescription as waveguide formation. The requirement for a periodic index perturbation can be implemented via the real or imaginary part of the refractive index. Therefore, the techniques of gain/loss modulation and real or effective index modulation described in Section 0 can be applied to produce a DFB grating. To produce a real index modulation, the technique of quantum well intermixing (QWI) can be used to change the bandgap of the quantum wells, as is known in the art, thereby changing the real index of refraction. A QWI waveguide would look similar to the DBR mirror portion of FIG. 4(b). If such intermixed/unmixed quantum wells were electrically pumped, then the different density of states would also produce a periodic perturbation in the gain or loss of the waveguide, thereby producing an imaginary refractive index grating. Examples of the effective index and resonant wavelength modulation approaches are given in FIG. 7 and FIG. 8, respectively. The above examples, coupled with the techniques described in Section 0, will suggest other possible methods of grating formation to one skilled in the art.

### Optical Taps

Useful light can be extracted from the device via an optical tap. We define optical tap as a section of device where either top or bottom mirror is of sufficiently reduced reflectivity as to allow the desired amount of light to escape normal to the surface. An optical tap can be formed by the removal or omission of mirror periods or portions of a period, or by the removal or omission of additional reflective layers, such as Au, or by the addition of an anti-reflective coating. In one extreme, an optical tap can consist of a simple AR coating disposed directly on the cavity.

In general it is desirable to shape the output beam for coupling to a fiber or focusing on another external optical element. Both the vertical and lateral profiles of the optical tap must be considered when shaping the beam. Furthermore, the designer must take into account the near field mode profile, which is a sin2 standing wave if the tap is placed over a grating. If the grating is terminated at the optical tap interface, or no grating exists adjacent to the optical tap, then the longitudinal solution is a traveling wave whose intensity falls exponentially with distance from the edge of the optical tap.

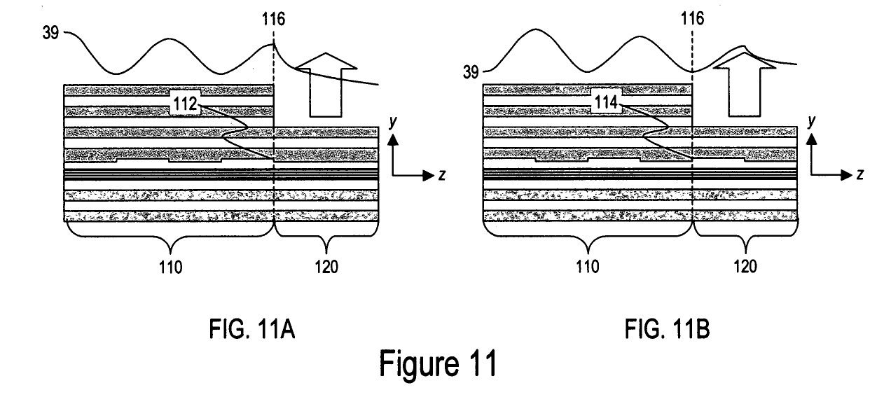

Changes in the vertical or lateral confinement of the waveguide represent a change in the phase of propagation, also known as a discontinuity. Since perturbation of the waveguide causes an additional reflection, care must be used when positioning the optical tap over a grating. Consider the case of an abrupt change in the number of mirror pairs in the vertical direction, as shown in FIG. 11. FIG. 11(a) shows a side view cross section of a waveguide with a grating section 110, optical tap 120 and boundary 116 between them. The longitudinal near field mode profile 39 is shown above. The reflection of an abrupt discontinuity, which acts as a bulk mirror, can be added in-phase to the grating by making it coincident with a down step 112 in the grating index, as shown in FIG. 11(a). Conversely, an abrupt discontinuity can be hidden in a null of the longitudinal standing wave by making it coincident with a up step 114 in the grating index, as shown in FIG. 11(b). In this case the discontinuity is made essentially invisible to the longitudinal cavity. Alternatively, the discontinuity can be placed at an intermediate point between these two extremes, in which case the phase of the reflection must be taken into account.

Beam shaping in the vertical direction can be accomplished by tailoring the thickness (phase) and/or reflectivity (loss) of the output layers. If the changes in thickness are small, the problem can be treated as a perturbation of a vertical plane wave and longitudinal plane wave. Shaping of the vertical wave can be accomplished via a variation in the thickness of a top layer or layers. Such a thickness variation leads to a phase difference in the output wave as a function of distance along the z-axis. A taper in the output layer will therefore have a lens-like effect and result in some focusing of the output beam.

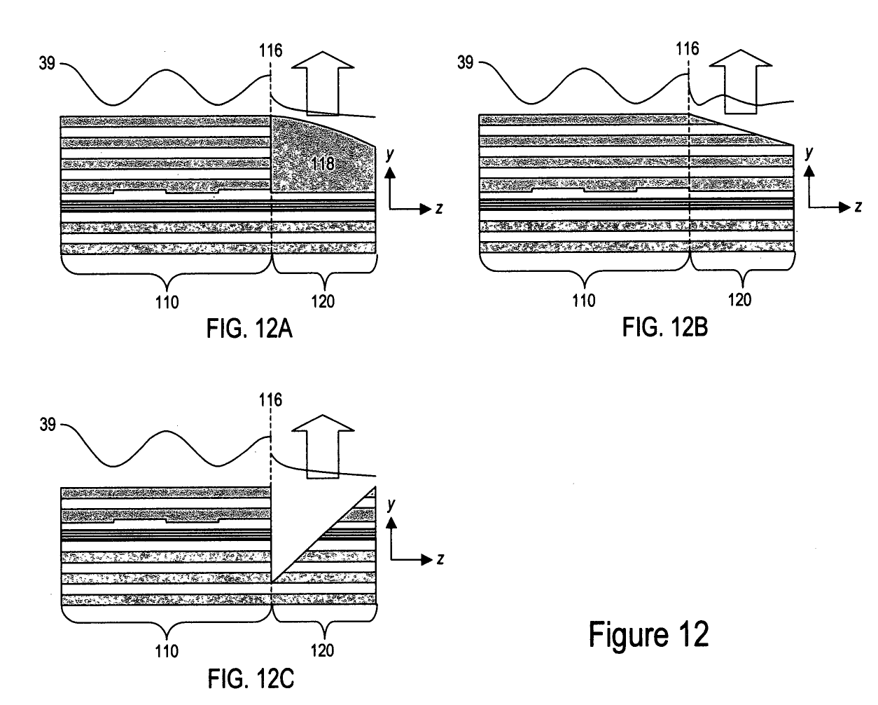

FIG. 12 shows a side view cross section of a waveguide with a grating section 110, optical tap 120 and boundary 116 between them. The longitudinal near field mode profile 39 is shown above. FIG. 12(a) illustrates the case of pure phase modulation via a curved tapering of a homogeneous output coupling layer 118. If multiple DBR layers are tapered, as in FIG. 12(b), then phase and reflectivity are modulated simultaneously, leading to a more complex output beam profile. Such a profile is best simulated numerically. Finally if the changes in thickness are very large such that the vertical profile has significant overlap with the vertical optical mode, as in FIG. 12(c), then the situation must be treated as in the case of bulk optics. In this exemplary embodiment, a 45° mirror is formed through the vertical structure such that it penetrates into the bottom DBR mirror, as illustrated in FIG. 12(c).

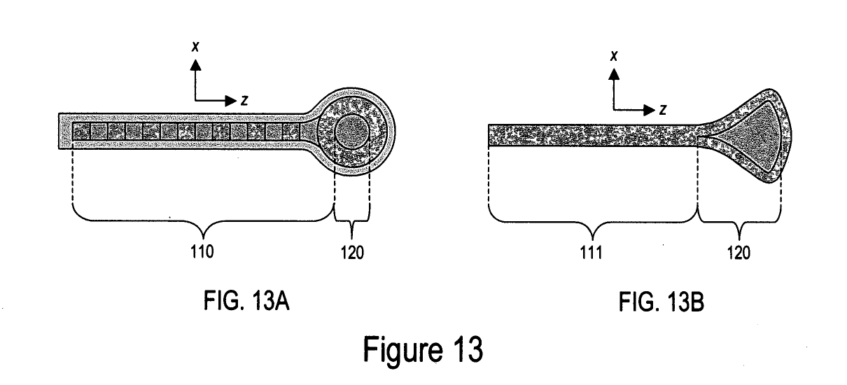

Beam shaping in the lateral and longitudinal directions can be accomplished via a tapering of the waveguide and/or aperture. FIGS. 13(a) and 13(b) illustrate examples of lateral tapers that can be used in various devices. Taps 120 can be placed over a grating 110 and the waveguide can be tapered to approximate a radial grating, as shown in FIG. 13(a), thereby giving the standing wave a circular lateral profile. For traveling wave optical taps, the waveguide can be tapered linearly or exponentially, as shown in FIG. 13(b), so as to create a more uniform output beam from the exponentially decaying field in the waveguide. Other tapers can be used to create gaussian beams or to beam expand for fiber mode matching.

### Planar Waveguide Vertical Cavity Laser

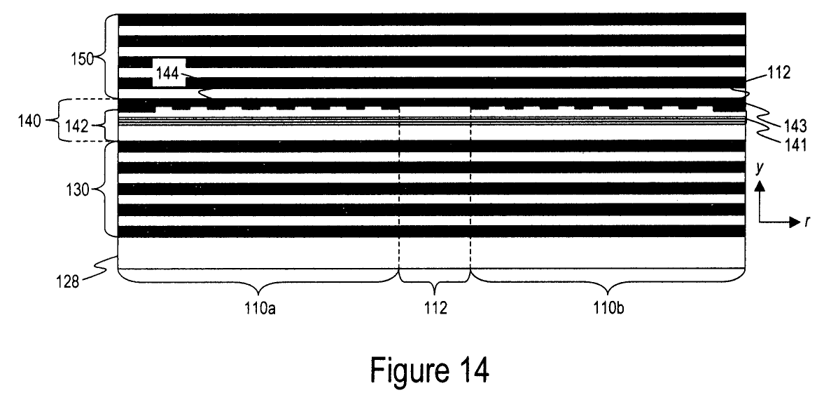

An exemplary embodiment of the PWVCL is illustrated in FIG. 14. A bottom DBR mirror 130 is formed on a substrate 128. A 1-λy vertical cavity 140 containing an active region 141 is formed on the bottom mirror. A top mirror 150 is disposed adjacent to the cavity 140. In this embodiment, the bottom mirror 130 is made of semiconductor material, the cavity is a hybrid of semiconductor (¾λy) 142 and dielectric or regrown semiconductor (¼λy) 143, and the top mirror 150 is made of dielectric or regrown semiconductor material. The vertical cavity wavelength, λy, as well as the center wavelength of the mirrors, is chosen to be slightly greater than the intended lasing wavelength, λ, according to Equation 1. The vertical cavity can have thickness (m+1)λy/2, where m is an integer. However, if m=0 the center of the cavity will lie at a null in the standing wave intensity pattern, thereby reducing the optical confinement factor significantly. Also, if m>1, the cavity can support more than one vertical mode and additional mode selectivity can be necessary. The cavity 140 can be composed of lattice-matched semiconductor material, or a hybrid combination of semiconductor and a metamorphic and/or dielectric or material. In the case of a hybrid cavity, it is advantageous to place the hybrid interface at a null in the optical field intensity pattern so as to minimize scattering and absorption losses. The active region 141 can be composed of quantum dots, quantum wires, quantum wells, or a bulk active material that provides gain in the desired wavelength band. Exemplary dielectric materials include, SiNx, SiO2, ZnSe, MgF2, or other suitable materials. Exemplary semiconductor materials include InP/InGaAsP, GaAs/AlGaAs or other III-V or II-VI compounds. In addition to semiconductor and dielectric materials, one or both mirrors can be metamorphic or fused in nature, as is known in the art.

Still referring to FIG. 14, a planar grating 144 is formed in the (¾λy) 142 cavity in the radial direction. Alternatively, the grating can be placed somewhere within the top or bottom mirror, at the surface of the top mirror, or at the substrate/bottom mirror interface. Gratings placed further from the cavity interact with a weaker optical field and can require a deeper grating to produce the desired coupling factor. The radial wavelength, λr, is chosen according to Equation 2 for the desired lasing wavelength, λ. The period of the grating, Λ, is chosen to equal λr/2. The depth of the grating is chosen to achieve the desired coupling factor, κ. Larger κproduces greater peak intensity, which can be desirable for intracavity output, and allows for fewer grating periods leading to smaller devices. However, the resonance frequency deviation of any given vertical cross section (grating peak or trough) must receive adequate vertical mirror reflectivity to avoid excessive mirror loss in the vertical direction.

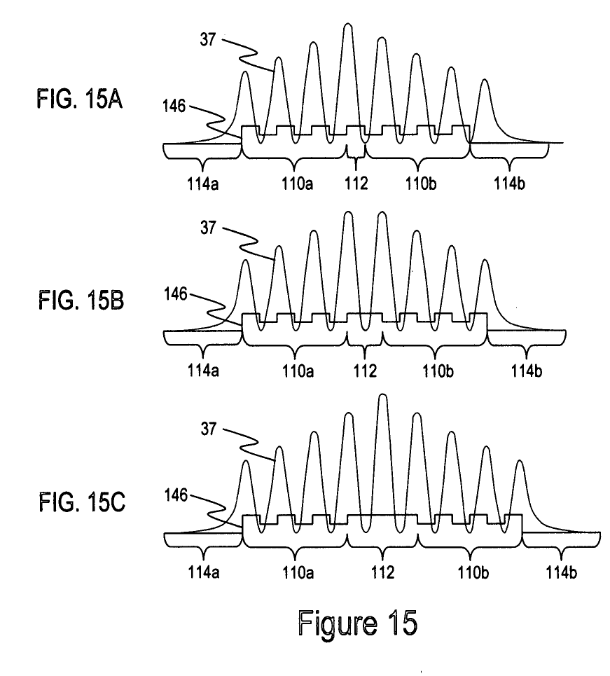

Again referring to FIG. 14, a 1-λr cavity 112 is placed at the center of the grating to fix the position of the peak optical power and select the radial wavelength. Alternatively, the grating cavity can have thickness (m+1)λr/2, where m is an integer. FIGS. 15(a), 15(b) and 15(c) illustrate the index profile 146 and standing wave pattern 37 for cavities 112 of diameter ¼λ, ½λ, and 1-λ. The lateral index profile 146 is composed of cavity 112, grating 110, and termination sections 114. If D=¼λ, as in FIG. 15(a), the standing wave pattern does not precisely match the Bragg condition, i.e. the peaks and nulls of the optical field do not always occur at the index transitions. If D=½λ, as in FIG. 15(b), the peak in the standing wave pattern will have two equal lobes, which can not be suitable for coupling out of the surface and into a fiber. Also, if m>1, the cavity can support more than one radial mode. Only if D=1-λ, as in FIG. 15(c), is there is a single optical lobe at the peak intensity point, which can be best suited for coupling out of the surface and into a fiber.

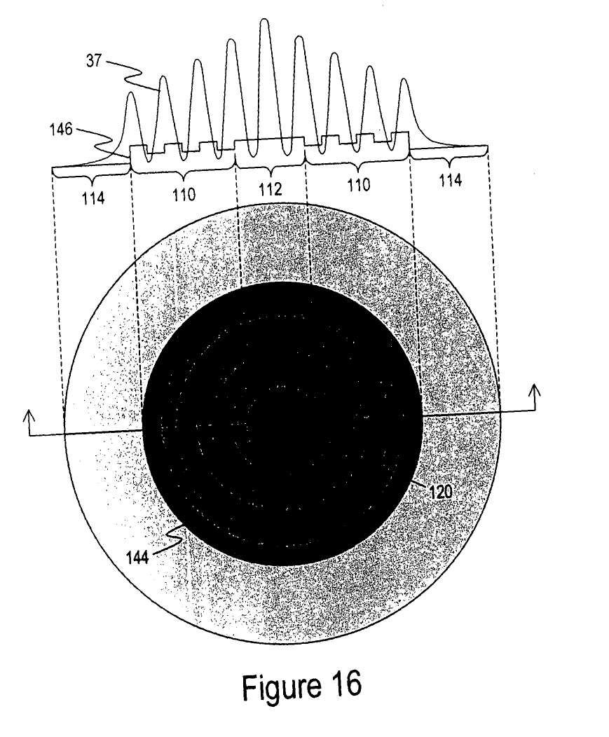

A top view of and exemplary PWVCL with radial grating pattern 144, is shown in FIG. 16. The radial index 146 and standing wave profiles 37 are also shown. The radial index profile 146 is composed of cavity 112, grating 110, and termination sections 114. The output aperture location 120 allows only the central lobe to exit from the device. The grating 110 is terminated 114 by a vertical layer stack whose refractive index is less than that of the overall effective index of the vertical DBR and radial grating structure, as described hereinabove. This assures an evanescent wave beyond the edge of the grating and provides for the lowest optical losses. Such a refractive index can be achieved via oxidation, as is known in the art, or by a large thickness step, giving rise to a large index step, as illustrated in FIG. 14. Alternatively, gain or loss modulation can be used to terminate the grating, as described hereinabove. Finally, the grating can be simply terminated without change in index, gain or loss, in which case light will be emitted from the grating edge. This technique is useful for integrating the laser with other devices described below.

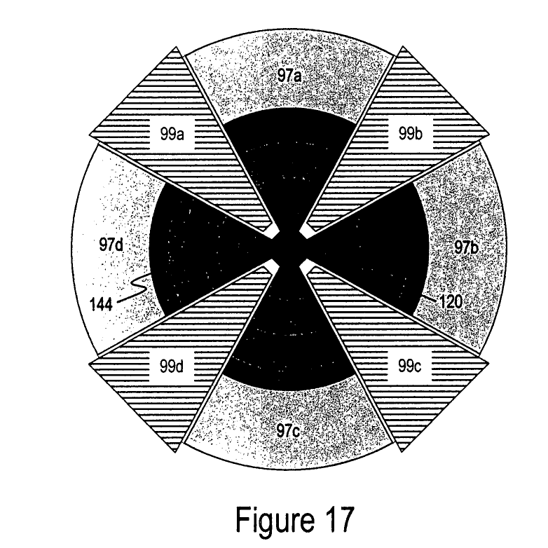

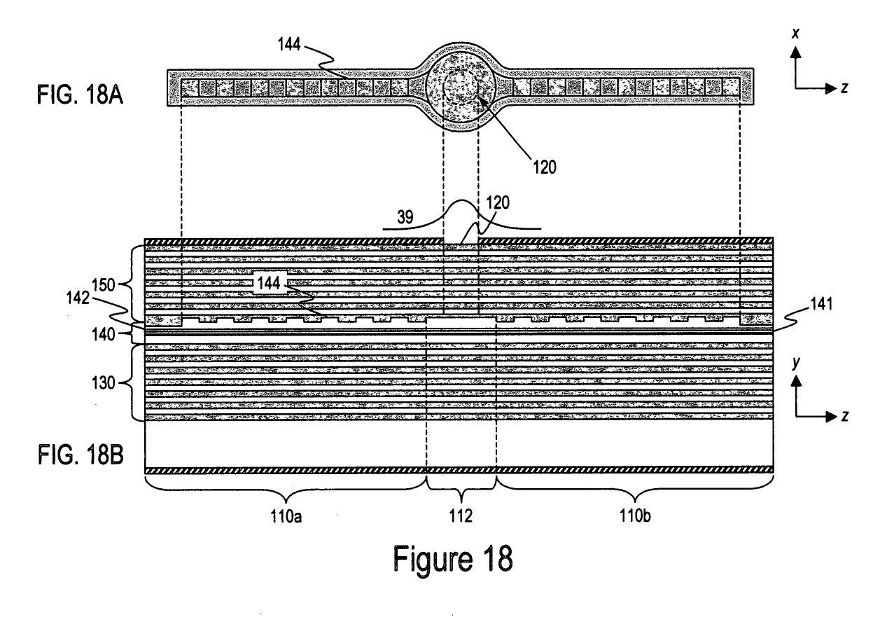

In an alternative embodiment, the radial grating pattern 144 can be broken up into azimuthal sections 97, as shown in the four-lobed pattern of FIG. 17. In this embodiment, four intracavity contacts 99 are used to pump the cavity and lobes 97 in a uniform fashion. Any azimuthal section of the circularly symmetric grating will produce a similar result, including sections that are asymmetric about the lateral cavity. At one extreme, the grating can be confined to a linear waveguide. FIG. 18 illustrates an exemplary embodiment of a linear waveguide, intracavity output PWVCL. A bottom DBR mirror 130 is formed on a substrate. A 1-λy vertical cavity 140 containing an active region 141 is formed on the bottom mirror. A top mirror 150 is disposed adjacent to the cavity 140. In this embodiment, the bottom mirror 130 is made of semiconductor material, the cavity is a hybrid of semiconductor (¾λy) 142 and regrown semiconductor (¼λy), and the top mirror 150 is made of regrown semiconductor material. The waveguide can be formed by the resonant wavelength modulation method. The linear waveguide has the advantage that it is more easily pumped via intracavity contacts. Restricting the area of the device has the overall advantage of reducing the amount of material to be pumped, and therefore the total drive current. Larger devices, on the other hand, can produce more output power.

Forming a waveguide in one of the device dimensions determines the wavelength of the light in that dimension and therefore contributes to the overall lasing wavelength via Equation 1. This fact must be kept in mind when designing a PWVCL, and, in fact, is one of the ways to tailor the wavelength for certain applications. Some examples of wavelength tailoring will be provided below.

The location of the optical taps 120 for the circularly symmetric, four-lobed, and linear grating configurations are shown in FIGS. 4, 5, and 8, respectively. Note that in these embodiments the optical taps are centered within the cavity. Alternatively, an optical tap can be placed anywhere within a linear or radial grating or even beyond the edge of a grating. If the optical tap is placed over a shift in the grating that is not at the peak power point, then the tap interacts with light of reduced intensity and fabrication of the tap can be more tolerant of process variations. The section of grating to the right of the tap can be active or passive. The optical tap allows a variety of other surface-emitting devices to be made, some examples of which are described below.

### Active Waveguides

In an exemplary embodiment of an active waveguide, vertical optical confinement is achieved via the effective cladding method, while lateral optical confinement is achieved via the resonant wavelength modulation technique, also described the waveguide section herein. An active waveguide is formed by placing an electrically isolated pair of contacts, such as can be used to apply a bias, on or adjacent to a section of the longitudinal waveguide. If the top mirror is non-conductive, then an intracavity contact is placed adjacent to the waveguide, as in FIG. 8. If the top mirror is electrically conductive, then an electrode is placed on top of the waveguide, as in FIG. 9.

Under normal circumstances, the quantum wells are absorbing at the lasing wavelength with an absorption coefficient of order 104 cm-1. At this absorption level the unbiased waveguide losses can be excessive for many practical applications. In order to reduce or eliminate these losses, the waveguide is forward biased just below or at transparency (zero material losses), respectively. Any amount of loss can be selected by varying the amount of current injected. The amount of bias can also be adjusted to compensate for scattering losses due to bends and turns in the waveguide. However, should the forward bias exceed the losses in any given section of active waveguide, the section then becomes a traveling wave amplifier. A surface-receiving and emitting (discrete) version of this device can be made by placing optical taps at each end of the waveguide.

Alternatively, to reduce waveguide losses, quantum well intermixing can be used to modify the unbiased electron-hole transition wavelength, as is known in the art. In this technique localized proton implantation and anneal are used to change the shape of the wells from square to rounded, thus raising the transition energy and making them more transparent at zero bias.

Combiners and Splitters Important functions in the design of PICs are fan-in (combining) and fan-out (splitting). Fan-in combines light from two or more separate waveguides into a single waveguide, while fan-out does the reverse. In all of the following embodiments vertical optical confinement is achieved via the effective cladding method described herein, while lateral optical confinement is achieved via the resonant wavelength modulation technique, also described herein. Also, waveguide losses can be reduced via the quantum well mixing technique described herein. Furthermore, a discrete, surface-receiving and emitting version of any of the following devices can be made by placing an optical tap and/or by creating and etched or cleaved facet at the end of each waveguide.

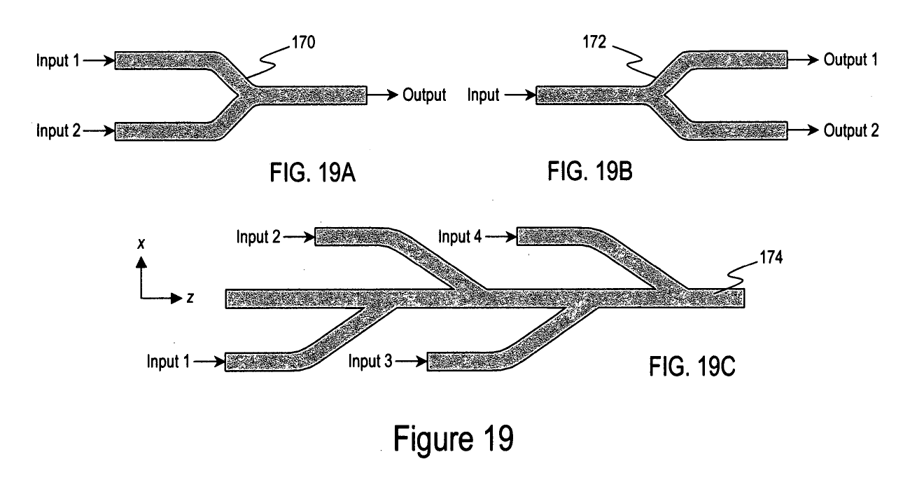

In an exemplary embodiment, a combiner 170 can be formed by joining waveguides in a “Y” formation, as shown in FIG. 19(a). A splitter 172 can be formed from the same structure by swapping inputs and outputs, as shown in FIG. 19(b). If more than two waveguides need to be joined, a sequential combiner 174 can be used, as shown in FIG. 19(c). Alternatively, combining can be achieved by cascading Y-combiners (not shown). Alternatively, three or more waveguides can be joined or split simultaneously (also not shown), although care must be taken to avoid excessive losses due to severe bends in the waveguide. The advantages of the Y-combiner are its simplicity, robustness and insensitivity to waveguide phase variation and wavelength.

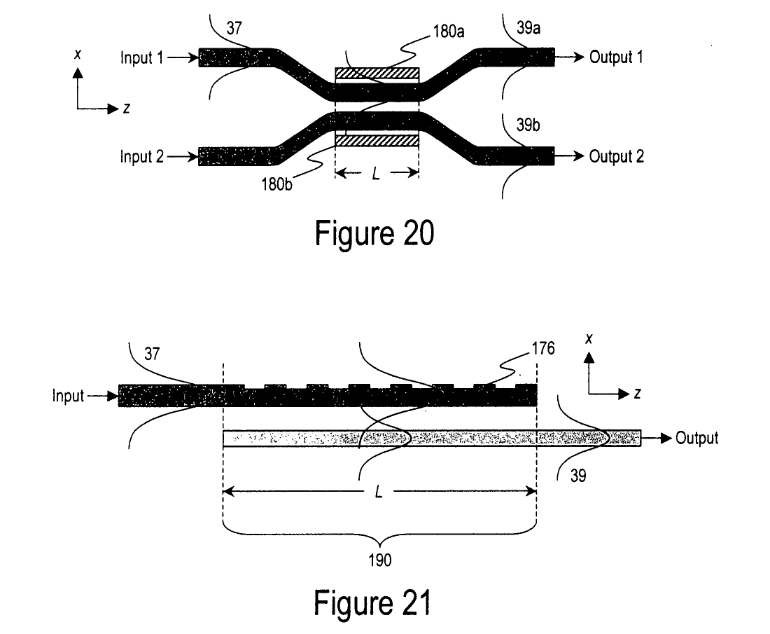

In an exemplary embodiment, a coupled waveguide is used to create a splitter, as illustrated in FIG. 20. In this embodiment, no wave is incident upon input 2. In this device two waveguides are brought closer and closer together until the lateral optical mode 37 from one waveguide penetrates the opposing waveguide. The overlap of the optical mode occurs over a section of parallel waveguides of length L. For significant coupling to occur, the propagation constants, β1 and β2, of the waveguides must be substantially the same. If necessary, a forward bias is applied via control electrodes 180 placed on or near the waveguides to reduce the amount of loss and/or adjust the relative phase of the waveguides, and thereby fine-tune tune the coupling between them. When β1=β2, the waveguides are said to be phase matched. In this case, as the light propagates down the first waveguide it is coupled to the second waveguide over an interaction length L=πκ/2, where κ is the coupling coefficient. If L=πκ/4, then half the light will be coupled to the second waveguide, thereby forming a 50/50 splitter. Any amount of splitting can be chosen by adjusting the waveguide phase, interaction length, or phase tuning via electrode bias. This process can be repeated indefinitely to split a wave into an arbitrary number of waveguides.

### Switches and Mixers

Important functions in the design of PICs are switching and mixing. Switching takes light from one waveguide and switches it to another or selects between one of two or more outputs. Mixing combines light from two or more separate waveguides into one or more separate waveguides. In all of the following embodiments vertical optical confinement is achieved via the effective cladding method, while lateral optical confinement is achieved via the resonant wavelength modulation technique, and further waveguide losses can be reduced via the quantum well mixing technique. Furthermore, a discrete, surface-receiving and emitting version of any of the following devices can be made by placing an optical tap and/or by creating and etched or cleaved facet at the end of each waveguide.

In an exemplary embodiment, a grating-assisted co-directional coupler (GACC) is formed as indicated in FIG. 21. A lateral corrugation 176 of period A is inserted in the input waveguide such that β2=β1+2π/Λ, where β1 and β2 are the phases of the input and output waveguides, respectively. In operation, an input wave 37 is incident upon the first waveguide, and coupled to the second over the interaction span 190 of length L. This approach is used primarily when the phases of the waveguides are sufficiently mismatched so as to prevent adequate coupling. The period of this type of grating tends to be tens of wavelengths long, much longer than a typical, first-order, reflective grating. This type of coupler is wavelength-specific, that is, it also acts as a filter, although, in general, the filter pass band is rather broad.

In an alternative embodiment, the coupled waveguide of FIG. 20 is used to create a switch. In this embodiment, no wave is incident upon input 2. The input wave 37 passes through the interaction length, L. A forward or reverse bias is applied to the control electrodes 180 to tune the relative waveguide phases, thereby determining which output the wave will exit. A reverse bias voltage can change the index of refraction via the electro-optic and QCSE effects, as discussed in Section 0 below, with a very fast response time. Relatively speaking, a forward bias can produce a larger change in refractive index via carrier injection. However, carrier lifetime effects limit the index modulation speed to a few hundred megahertz.

In an exemplary embodiment, the coupled waveguide of FIG. 20 is used to create a mixer. In this embodiment, the waves to be mixed are incident upon inputs 1 and 2. The waves couple over to the opposite waveguide over an interaction length L=πκ/4, and emerge at the outputs as a mixture of both incident waves. Any amount of mixing can be chosen by adjusting the waveguide phase, interaction length, or phase tuning via electrode bias.

### Passive Waveguides

The drawback to an active waveguide is the amount of current it draws and the amount of power it dissipates. While acceptable for short distances, these quantities can be high for long, intra-chip distances. One solution is to use quantum well mixing to locally change the transition energy of the quantum wells, thereby rendering them largely transparent at the wavelength(s) of interest. Another solution is to add a low-loss, passive waveguide (PW) to the structure. In a passive waveguide vertical and lateral optical confinement can be formed by any of the real or effective index methods described herein.

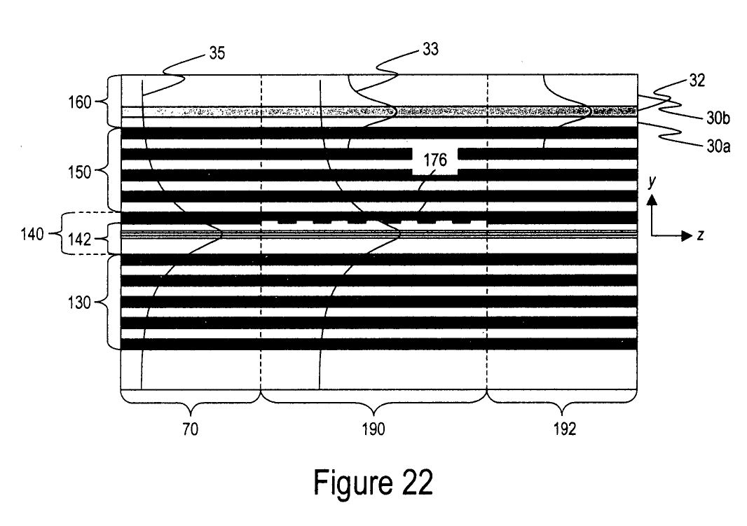

In an exemplary embodiment of a passive waveguide, a vertical structure similar to that illustrated in FIG. 14 is formed, as illustrated in FIG. 22. Lateral optical confinement is formed in the active waveguide via the resonant wavelength modulation. An active waveguide is formed in sections 70 and 190. A lower bulk cladding layer 30a is disposed adjacent to the top mirror. A core layer 32 is disposed on the lower cladding and patterned laterally into a rib or a ridge. Finally, an upper bulk cladding 30b is disposed on the core layer forming a passive waveguide 160. The passive waveguide 160 extends from sections 190 to 192. In operation, the wave with envelope function 35 is guided in the active waveguide section 70. It enters the GACC section 190 whereupon it is significantly coupled into the upper, passive waveguide 160 over an interaction length L with the aid of a grating 176. The coupled wave 33 continues on in the passive waveguide section 192 where it can be routed elsewhere in the PIC.

The rib in the core layer produces a slight index difference in the lateral direction and can be designed to support one or many lateral modes, as is known in the art. This embodiment utilizes a conventional vertical waveguide structure, albeit one that can be significantly phase-mismatched from the active waveguide. If the top mirror is made of semiconductor material, then the passive waveguide can be composed of semiconductor, metamorphic, or dielectric material, or a combination thereof. If the top mirror is metamorphic, then the waveguide can be composed of metamorphic or dielectric material, or a combination thereof. If the top mirror is dielectric, then the waveguide must be composed of dielectric or other suitable material, such as a polymer. Alternatively, the passive waveguide can be buried between the substrate and bottom mirror, or disposed adjacent to a wafer-fused mirror. Furthermore, the core and cladding layers can be comprised of stacks of layers to improve the vertical confinement.

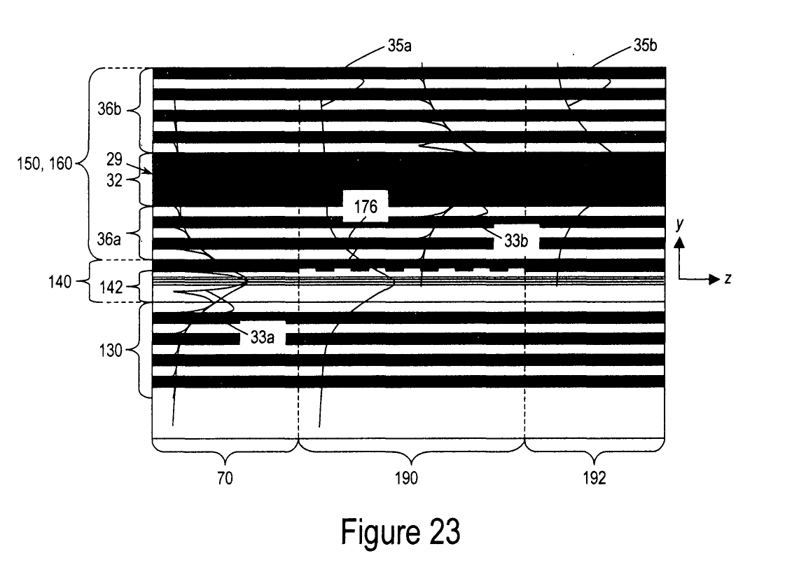

In an alternative embodiment, a passive waveguide is formed with effective cladding layers, as illustrated in FIG. 23. Lateral optical confinement is formed in the active waveguide via the resonant wavelength modulation. An active waveguide is formed in sections 11a and 190. A lower effective cladding layer 36a is uses the same DBR layers as the bottom portion of the top mirror 150. A stack of core layers 32 is disposed adjacent the bottom portion of the top mirror 150. The core 32 is comprised of a ½-λ bottom stepwise graded index layer 32, a ½-λ high index waveguide layer 29, and a ¼-λ top stepwise graded index layer. An upper effective cladding layer 36b is disposed adjacent to the core layer 32 forming a passive waveguide 160. The passive waveguide 160 extends from sections 190 to 192. Note that the passive waveguide 160 vertical structure uses many of the same layers as the active waveguide top DBR 150. In operation, the vertical standing wave 33a with envelope function 35a is guided in the active waveguide section 70. It enters the GACC section 190 whereupon it is significantly coupled into the upper, passive waveguide 160 over an interaction length, L, with the aid of a grating 176. The coupled wave 33a with envelope function 35b continues on in the passive waveguide section 192 where it can be routed elsewhere in the PIC.

In order to retain the correct mirror phasing, the core 32 must be of optical thickness (2 m+3)λ/4, where m is an integer ≧0. Note that the passive waveguide 160 is not symmetric, and that the upper portion of the standing wave pattern 33b is out of phase with the mirror close to the core 32. With sufficient mirror periods, however, the standing wave rephases with the upper mirror layers and they once again form an effective cladding layer 36b. The advantage of this embodiment is that the passive waveguide can be more closely phase-matched to the active waveguide below. This would facilitate coupling from active to passive waveguides and vice versa.

A variety of methods can be used to switch light from the active waveguide into the passive waveguide and vice versa. The methods include: phase matching via modification of the vertical structure, such as placement over an optical tap, phase matching via modification of the lateral structure, such as a variation in waveguide width, phase matching via modification of the longitudinal structure, such the GACC, or phase matching via carrier induced index change achieved through forward or reverse bias of the active waveguide.

### Filters

A variety of filters can be formed by placing a longitudinal grating inside a waveguide formed within the vertical cavity structure. The grating selects a single longitudinal wavelength, while the vertical and horizontal wavelengths are determined by the VCL and waveguide structures, respectively. The overall filter wavelength, λfilter, is then given by Equation 1. In all of the following embodiments vertical optical confinement is achieved via the effective cladding method described herein, while lateral optical confinement is achieved via the resonant wavelength modulation technique, also described herein, and further waveguide losses can be reduced via the quantum well mixing technique described herein. Furthermore, a discrete, surface-receiving and emitting version of any of the following devices can be made by placing an optical tap and/or by creating an etched or cleaved facet at each end of the waveguide.

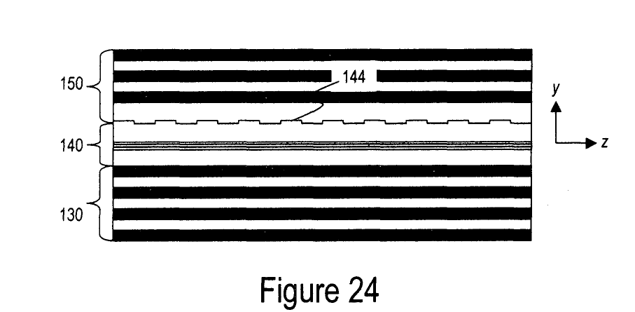

In an exemplary embodiment of a grating filter, shown in FIG. 24, a bottom DBR mirror 130 is formed on a substrate. A 1-λy vertical cavity 140 is formed on the bottom mirror. A top mirror 150 is disposed adjacent to the cavity 140. A uniform grating 144 of period Λg can be used to select a single, longitudinal wavelength near the Bragg wavelength, λB=2Λg. Alternatively, placing a ¼-wave (Λg/2) shift within a uniform grating allows transmission precisely at the Bragg wavelength. A comb of wavelengths (additional longitudinal modes) can be passed by the filter if the cavity is extended by an integer multiple of Λg/2. As the longitudinal cavity is extended, the wavelength spacing shrinks and the number of modes in the comb grows. The center wavelength, however, remains at Λg. Two uniform gratings separated by a cavity are sometimes referred to as a sampled grating. It is important to note that either the amplitude or the phase of the gratings can be sampled. Sampled gratings are particularly useful in making an extended tuning range filter.

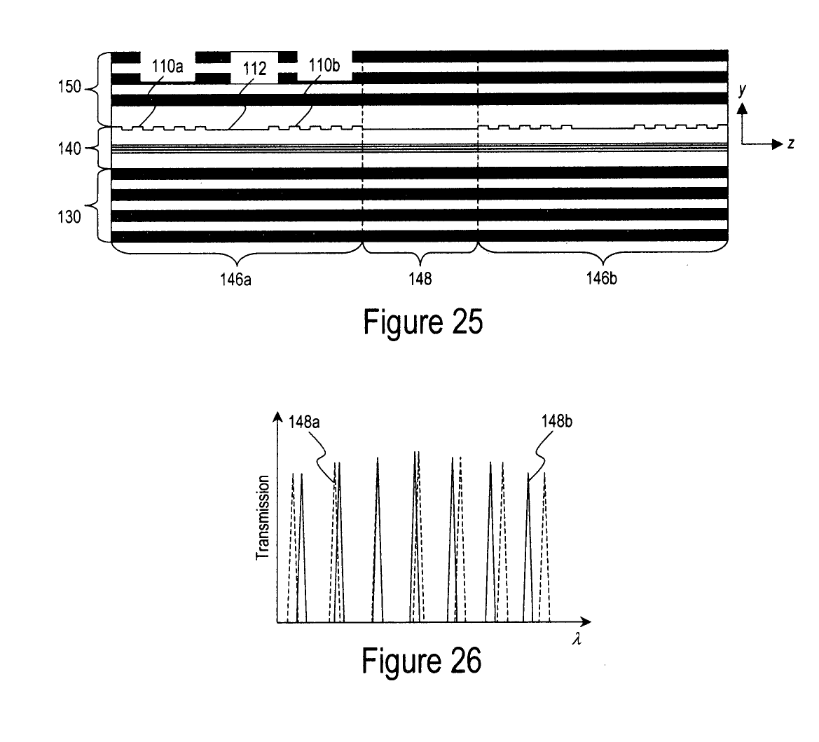

In an exemplary embodiment of an extended tuning range filter, illustrated in FIG. 25, a bottom DBR mirror 130 is formed on a substrate. A 1-λy vertical cavity 140 is formed on the bottom mirror. A top mirror 150 is disposed adjacent to the cavity 140. A longitudinal cavity 148 is surrounded by sampled gratings (mirrors) 146a, 146b of slightly different period. The sampled grating sections 146 are comprised of a cavity 112 surrounded by uniform gratings 110a, 110b. Separate electrodes are formed on each section 146a, 148, 146b. As discussed above, the periodic sampling creates a corresponding transmission spectrum with periodic maxima in the frequency domain, as illustrated in FIG. 26. By sampling the gratings at different periods, reflection maxima with different wavelength periods 148a and 148b are created in each mirror. The comb function of each mirror can be tuned via its electrode. Referring to FIG. 26, if a transmission peak from one mirror coincides with one from the other mirror, then all other peaks will be out of alignment, and the product of the two transmission spectra will only have one maximum. As a result, the filter will provide good, single frequency filtering. If all three sections are tuned simultaneously, true continuous tunability of a single frequency filter is possible.

In an alternative embodiment, a grating-assisted co-directional coupler (GACC) is formed as indicated in FIG. 21 and discussed herein. Although this type of coupler is wavelength-specific, in general the filter pass band is rather broad and better suited to separating widely spaced channels. On the other hand, with the dispersion curves of the two waveguides nearly parallel, the filter can be made widely tunable with only a small index change in either waveguide. If narrow tuning is desired, a multi-stage filter can be used.

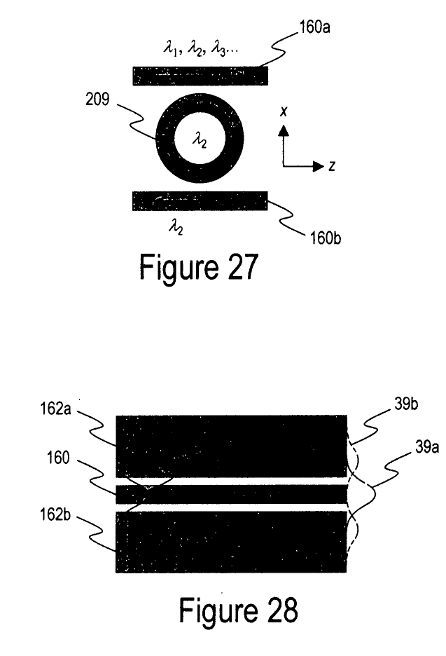

In an alternative embodiment, a resonant ring filter is formed as indicated in FIG. 27. In this embodiment, a resonant ring 209 is formed adjacent to an active or passive waveguide 160a. An additional active or passive waveguide 160b is formed adjacent to the ring 209. As multiple wavelengths (λ₁, λ₂, λ₃, etc.) are coupled out of the waveguide 160a, they propagate around the ring 209 and interfere with themselves. Only that wavelength, e.g. λ₂, that interferes constructively (is resonant) can propagate many round trips and is tapped off by the second waveguide 160b. Thus, rings of different radius can be used to select different optical frequencies from an incoming signal. The smaller the ring the greater the free spectral range (FSR) and the fewer the number of wavelengths it will select. Conventionally, resonant rings suffer from size limitations due to scattering losses when they are made small. This limitation can be overcome in the current invention by pumping the active resonant ring waveguide to create gain.

### Modulators

In all of the following modulator embodiments vertical optical confinement is achieved via the effective cladding method, while lateral optical confinement is achieved via the resonant wavelength modulation technique, and further waveguide losses can be reduced via the quantum well mixing technique. Furthermore, a discrete, surface-receiving and emitting version of any of the following devices can be made by placing an optical tap and/or by creating an etched or cleaved facet at each end of the waveguide.

An exemplary embodiment of an electro-absorption modulator can be formed by creating a section of active waveguide. In operation, the electrodes are used to apply a reverse bias to the quantum wells in the waveguide. This shifts the absorption edge of the quantum wells to longer wavelengths such that the lasing wavelength sees greater attenuation. This is the normally on mode of operation (high transmittance at zero bias), i.e. the modulator is more transmissive when no bias is applied. It should be noted, however, that, since the modulator uses the same quantum wells as the integrated laser, the absorption coefficient will be fairly high, even at zero bias. In this case a slight forward bias can be used to improve the transmissivity of the on state.

Alternatively, an electro-optic modulator can be formed from any of the switching methods. In this case only one output waveguide is used and the modulation depth is determined by the efficiency of the switch. In an exemplary embodiment a switch is based on the linear electro-optic effect and the quadratic quantum confined Stark effect (QCSE), as shown in FIG. 20. An alternative method of operating the same device is to slightly forward bias the quantum wells and thereby quench the exciton resonance due to the screening of the Coulombic interaction. A device using this effect is called a barrier reservoir and quantum well electron transfer (BRAQWET) modulator. In an alternative embodiment a switch utilizes a GACC, as shown in FIG. 21.

In an alternative embodiment, a guide/anti-guide modulator can be formed as indicated in FIG. 28. A field induced waveguide section 160 is formed in the center and field induced cladding sections 162 are formed on either side of it. In operation, a reverse bias is applied to either the waveguide section 160 or cladding sections 162 to create either a lateral index guide or antiguide profile, respectively. The output optical mode appears as guided 39a or antiguided 39b, respectively. Radiated energy in the antiguiding state must be spatially filtered in the output guide. As in the EO modulator case, the electro-optic effect is used to modify the refractive index of the guide and cladding regions without affecting absorption. However, unlike the EO modulator, it does not rely upon length-dependent mode beating or interference effects.

### Amplifiers

An optical amplifier can be formed by creating a section of active waveguide, as described herein. In operation, the contacts are used to apply a forward bias to the quantum wells in the waveguide so as to create gain. To avoid amplification of spontaneous emission (noise), the current must be kept below threshold in the longitudinal direction. To prevent lasing in the longitudinal direction reflections from the input and output must be kept to a minimum. Lasing in the vertical direction is not detrimental to the performance of the longitudinal amplifier.

For the integrated version of this device, the waveguide is continuous and discontinuities that cause reflections can be minimized. A discrete, surface-receiving and emitting version of this device can be made by placing optical taps at either end of the waveguide. In this version, great care must be taken to minimize reflections at the input and output ports. This can be done by omitting the top mirror and adding an AR coating at the ports. Minimizing the port reflectivity advantageously increases the available amplifier gain, optical bandwidth, and saturation optical power, while at the same time minimizing the noise figure.

### Tuners

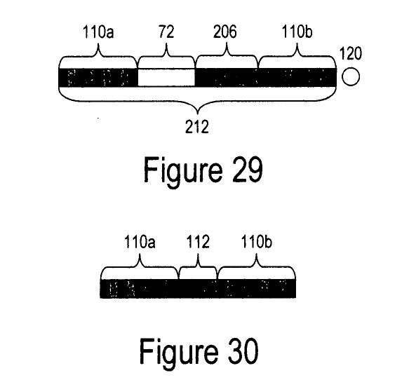

A tuning or phase section can be added to any device in which feedback occurs, including lasers, filters and resonant cavity amplifiers. A phase section is formed by adding electrodes to a section of waveguide within the longitudinal cavity. An exemplary embodiment of a tunable PWVCL is illustrated in FIG. 29. Vertical optical confinement is achieved via the effective cladding method and lateral optical confinement is achieved via the resonant wavelength modulation technique described herein. A gain section 206, equivalent to an amplifier described above, is formed in the waveguide. A tuning section 72 is formed adjacent to the gain section. A pair of grating mirrors 110 is formed such that they bracket the gain and phase sections. An optical tap 120 is formed at the output end of one of the grating mirrors. Alternatively, the output port can be formed via an etched or cleaved facet. One electrode is placed on each section, with the mirror electrodes tied together.

In operation, one section provides gain 206, one allows independent mode phase control 72, and one can shift the mode selective grating filter 110, respectively. By applying a control current or voltage to the grating sections 110, the index changes and the center wavelength of the mirror loss changes. Alternate axial modes can be selected as the grating loss minimum moves relative to the gain and modes. This is referred to as mode hopping. By applying a current or voltage to the phase control electrode 72, the index of the phase section changes, shifting the longitudinal modes of the cavity. Thus, by applying a combination of control signals to the grating 110 and phase control 72 sections, a broad range of wavelengths are accessible. A reverse bias voltage can change the index of refraction via the electro-optic and QCSE effects, with a very fast response time. A forward bias, on the other hand, can produce a relatively larger change in refractive index via carrier injection. However, carrier lifetime effects limit the index modulation speed to a few hundred megahertz.

### Photo Detectors

An exemplary photodetector can be formed by creating a section of active waveguide. In operation, the electrodes are used to apply a reverse bias to the p-i-n junction of the VCL structure. This will cause absorption in the transition wavelength range of the quantum wells and the photo-generated carriers will be swept out producing a photocurrent proportional to the intensity of the input light. The absorption band edge can be shifted to longer wavelength by increasing the reverse bias, in much the same way as the electro-absorption modulator described above. The resulting photodetector has a reasonably wide wavelength response (100 s of nm). Although a waveguide is not strictly necessary to create a photodetector, it will improve the efficiency (responsivity) of the detector due to the improved optical confinement. Also, if the electrodes are placed on or near a section of waveguide, it is possible to create a traveling-wave photodetector in which the photon-electron interaction length is extended to detect high-speed signals.

In an alternative embodiment, a narrow band, or resonant cavity, detector (RCD) can be formed, as indicated in FIG. 30. First, an active waveguide 111 is formed. A pair of grating mirrors 110 is formed so as to bracket the active waveguide 112. In operation, the active waveguide is reverse biased and the grating sections can be forward biased to reduce loss or provide gain (pre-amplification). A surface-receiving (discrete) version of any of the above-described photodetectors can be made by placing an optical tap at the input port of the waveguide.

### Alternative Integration Method

In an alternative method of integration, optical taps can be used to take the light out of the plane of the active waveguide between adjacent devices. An integrated or external reflective or diffractive element is then used to bend the light back into the active waveguide. The following examples illustrate some methods of out-of-plane integration methods.

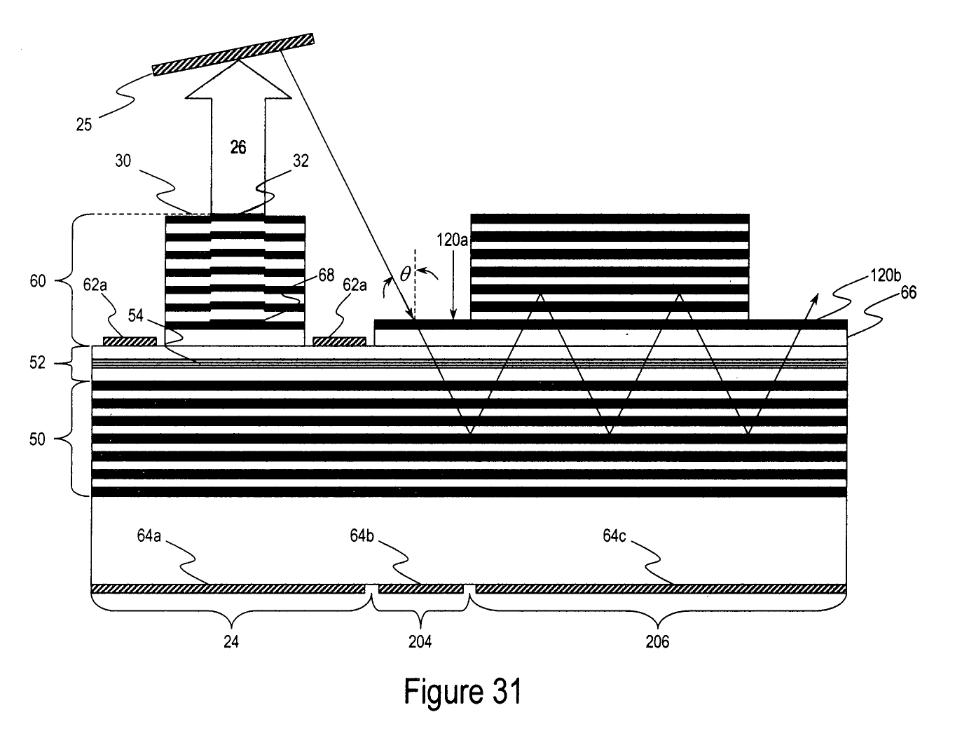

FIG. 31 illustrates an exemplary embodiment of an out-of-plane, externally integrated VCL 24, EAM 218, and amplifier 206. In this structure a bottom, electrically conductive, DBR mirror 50 is formed on a substrate. A 1-λ cavity 52, including MQW active layers 54 surrounded by cavity layers, is formed on the bottom mirror. A top, dielectric mirror 60 is formed on the cavity 52. A ½-λ phasing layer 66 is disposed on the cavity to ensure correct phasing of the mirror. A raised circle is formed in the first ¼-λ layer of the VCL top mirror 68 such that the layer is slightly thinner in the outer ring 30. From Equation 3, this results in lateral optical confinement. The EAM 204 and amplifier 206 sections share a common waveguide, a cross section of which is shown in FIG. 8. Lateral current confinement in all devices is achieved by ion implantation (not shown). In the present embodiment top, intracavity 62a and bottom 64a electrodes are used to electrically pump the VCL. Similarly, electrically isolated electrodes (not shown) are used to reverse bias the EAM 204 and forward bias the amplifier 206. These electrodes lie out of the plane of the Figure and are omitted for clarity. Electrical isolation can be achieved either through an isolation etch and/or ion implantation. The VCL top mirror 60 forms an optical tap and stimulated emission 26 is emitted from the top of the VCL 24. The light is reflected by an external element, in this case a mirror 25, such that it enters the EAM 218 at its optical input tap 120a formed by an AR coating. The modulated light then passes from the EAM 204 to the amplifier 206 section through the active waveguide. The amplified light exits at the optical output tap 120b, which is also AR coated. In summary, the VCL 24 and EAM 204 are integrated out-of-plane via an external mirror 25, whereas the EAM 204 and amplifier 206 are integrated in-plane via the active waveguide.

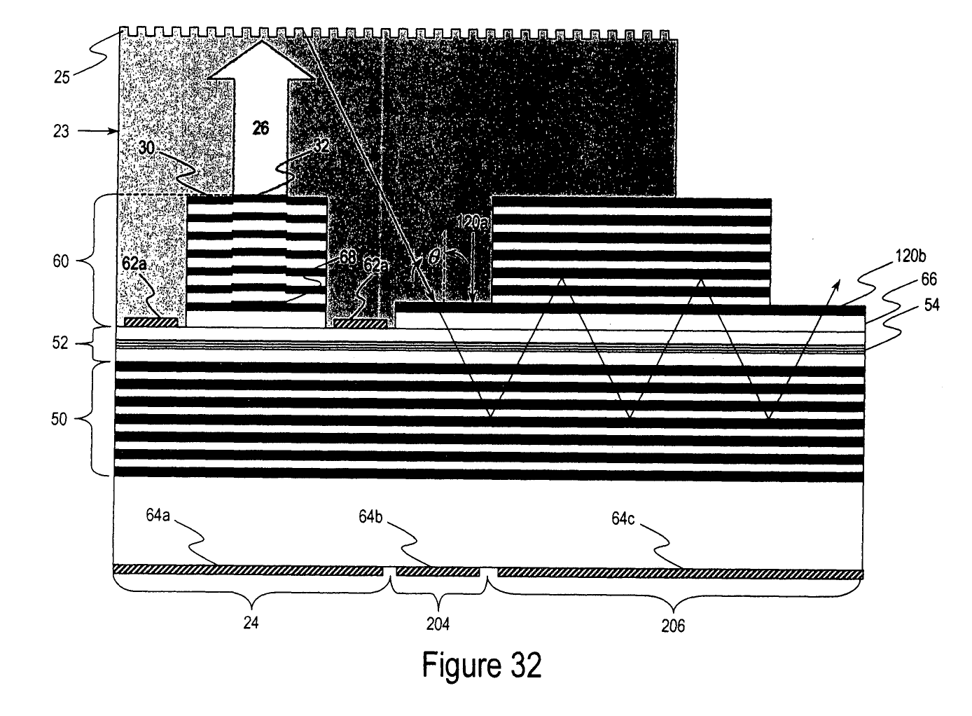

FIG. 32 illustrates an exemplary embodiment of an out-of-plane, monolithically integrated VCL 24, EAM 204, and amplifier 206. In this structure a bottom, electrically conductive, DBR mirror 50 is formed on a substrate. A 1-λ cavity 52, including MQW active layers 54 surrounded by cavity layers, is formed on the bottom mirror. A top, dielectric mirror 60 is formed on the cavity 52. A ½-λ phasing layer 66 is disposed on the cavity to ensure correct phasing of the mirror. A raised circle is formed in the first ¼-λ layer of the VCL top mirror 68 such that the layer is slightly thinner in the outer ring 30. From Equation 3, this results in lateral optical confinement. The EAM 204 and amplifier 206 sections share a common waveguide, a cross section of which is shown in FIG. 8. Lateral current confinement in all devices is achieved by ion implantation (not shown). In the present embodiment top, intracavity 62a and bottom 64a electrodes are used to electrically pump the VCL. Similarly, electrically isolated electrodes (not shown) are used to reverse bias the EAM 204 and forward bias the amplifier 206. These electrodes lie out of the plane of the Figure and are omitted for clarity. Electrical isolation can be achieved either through an isolation etch and/or ion implantation. The VCL top mirror 60 forms an optical tap and stimulated emission 26 is emitted from the top of the VCL 24. The light is reflected by a monolithically integrated element, in this case a diffraction grating 25 formed in polyamide 23, such that it enters the EAM 204 at its optical input tap 120a formed by an AR coating. The modulated light then passes from the EAM 204 to the amplifier 206 section through the active waveguide. The amplified light exits at the optical output tap 120b, which is also AR coated. In summary, the VCL 24 and EAM 204 are integrated out-of-plane via an external grating 25, whereas the EAM 204 and amplifier 206 are integrated in-plane via the active waveguide.

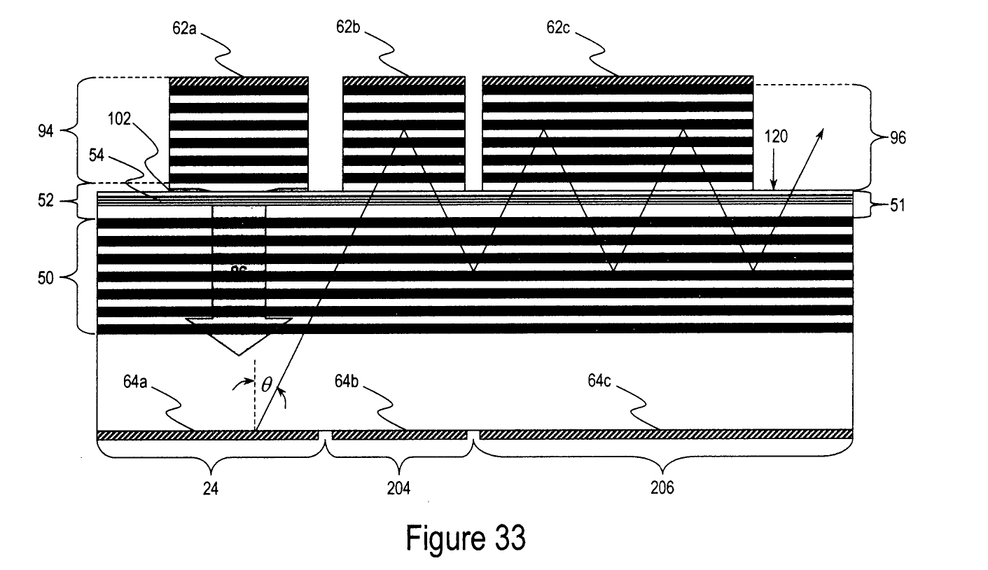

FIG. 33 illustrates an alternate, exemplary embodiment of an out-of-plane, externally integrated VCL 24, EAM 204, and amplifier 206. In this structure a bottom, electrically conductive, InP/InGaAlAs mirror 50 is formed on an InP substrate. A partial, ¾-λ cavity 51 including MQW active layers 54 is formed on the bottom mirror 50. A thin, oxidation layer 102 composed of high-Al-content AlGaAs is formed adjacent to the partial cavity 51. A ¼-λ metamorphic GaAs layer is disposed adjacent the partial cavity 51 forming a 1-λ hybrid cavity 52. A top, metamorphic, electrically conductive, GaAs/AlGaAs DBR mirror 94 is disposed adjacent to the hybrid cavity 52. The oxidizing layer, hybrid cavity layer and DBR are grown monolithically 96. Top, electrically isolated electrodes 62a, 62b, and 62c, consisting of a metal contacts, are formed on the top mirror and patterned in the shape of a VCL and a waveguide. Additional electrical isolation can be achieved through ion implantation (not shown). Using the metal as a self-aligning mask, the top mirror layers are etched down to just past the oxidation layer 102, using a standard etch technique as is known in the art. The structure is placed into an oxidizing environment and the high-Al-content layer 1022 oxidizes laterally inward until the desired waveguide width is achieved. Bottom electrodes 64a, 64b, and 64c are formed on the bottom surface of the substrate. Lateral optical and current confinement is achieved via the same oxide layers 102 as in the VCL 24, as described herein. These oxide layers lie out of the plane of the FIG. 33 are omitted for visual ease and clarity. In summary, the VCL 24 and EAM 204 are integrated out-of-plane via a monolithically integrated backside mirror, whereas the EAM 204 and amplifier 206 are integrated in-plane via the active waveguide.

### Photonic Integrated Circuits

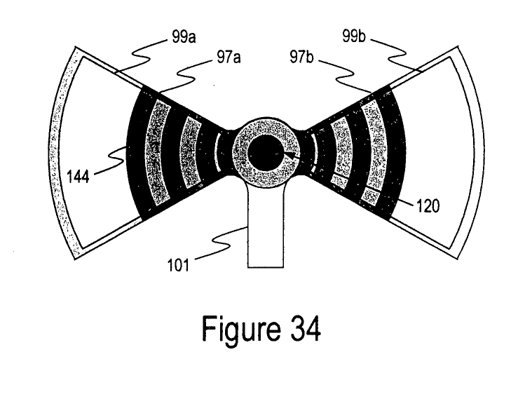

An exemplary embodiment of a PWVCL with an intracavity modulator is illustrated in FIG. 34. Vertical optical confinement is achieved via the effective cladding method described herein as well as the teachings for lateral optical confinement achieved via the resonant wavelength modulation technique. In the lateral (x) and longitudinal (z) directions, grating gain regions 97 are formed in the shape of a bow-tie surrounding a circular radial cavity. One set of electrodes 99 is used to pump the gain regions. A separate, annular electrode 101 is formed over the cavity. An optical tap 120 is formed inside the cavity electrode 101. This intracavity electrode 101 is used to modulate the laser. The modulator operates by changing the loss (or quiescence) of the cavity, also known as Q-switching. Compared to conventional VCLs, this structure has the advantage of producing more output power. Since the modulation occurs through variations in carrier density, this laser will produce chirp, or bias-dependent wavelength variation, as in a conventional VCL. However, the amount of radial wavelength chirp will be greatly reduced by the ratio of 1-λ cavity to the effective cavity length, which includes the penetration depth into the grating mirrors 144. Thus, if the effective radial cavity length is ten times (10×) greater than a conventional VCL, the modulation will produce 1/10th the chirp.

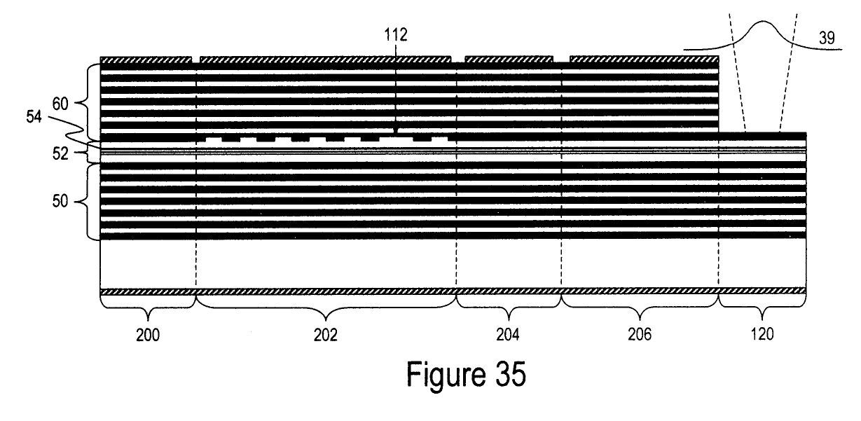

An exemplary embodiment of a PWVCL with integrated EAM and amplifier and power monitor is illustrated in FIG. 35. Vertical optical confinement is achieved via the effective cladding method and lateral optical confinement achieved via the resonant wavelength modulation technique, both of which are described herein such that a photodetector 200 is formed in the waveguide. A PWVCL 202 with a ¼-wave shift near the output end is formed adjacent to the photodetector and an EAM 204 is formed adjacent to the PWVCL. The EAM 204 is quantum well mixed to reduce absorption in the unbiased state. An optical amplifier 206 is formed adjacent to the EAM. An optical tap 120 is formed at the output end of the amplifier. Alternatively, the output port can be formed via an etched or cleaved facet. The four longitudinal sections of the waveguide are further defined by isolated electrodes. The photodetector 200 is reverse biased. The PWVCL 202 is forward biased above the lasing threshold. The EAM 204 is reverse biased such that the linear and quadratic electro-absorption coefficient can be used to produce significant modulation of the light output. The amplifier 206 is forward biased to produce signal gain.

In operation, the PWVCL 202 produces single mode lasing at a prescribed wavelength, with a greater amount of output power on the EAM 204 side than on the photodetector side. The light travels through the EAM 204 and is modulated by an applied voltage. The light travels through the amplifier 206 and is amplified whereupon it exits via the optical tap 120. A smaller fraction of the output power travels from the PWVCL 202 toward the photodetector 200. The light is absorbed by the photodetector 200 and generates a current proportional to the output power. The integrated devices produce a power monitored, externally modulated, amplified, single mode laser. This device incorporates many of the advantages of conventional VCSELs, including ease of fabrication, wafer-level testability, and fiber-matched output beam. It also incorporates many of the advantages of conventional EAM-DFBs, including wavelength-stable, single mode operation, low-impedance, high speed modulation, and high-power due to amplification. Finally, the overall level of integration, including power monitor, allows for reduced chip and packaging costs.

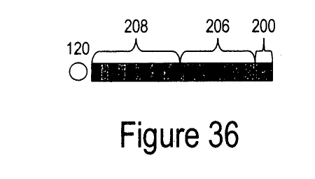

An exemplary embodiment of a filtered, preamplified photodetector is illustrated in FIG. 36. Vertical optical confinement is achieved via the effective cladding method. Lateral optical confinement is achieved via the resonant wavelength modulation technique. An optical tap 120 is formed at the input end of the waveguide. Alternatively, the input port can be formed via an etched or cleaved facet. A resonant cavity filter is formed in the waveguide adjacent to the optical tap. The filter section 208 comprises a DFB grating with a ¼-wave shift. The filter section 208 is forward biased below threshold to reduce the amount of absorption loss and/or to tune the filter. Alternatively, the filter section can be quantum well mixed. An optical amplifier 206 is formed adjacent to the filter 208. A photodetector 200 is formed adjacent to the amplifier 206. The three longitudinal sections are operated by isolated electrodes. In operation, the incoming signal is filtered by the resonant cavity filter 208, amplified by the amplifier 206, and absorbed by the photodetector 200. The integrated devices produce a narrow-band, pre-amplified receiver. A broadband, pre-amplified receiver can be made from the above-described elements by omitting the filter section.

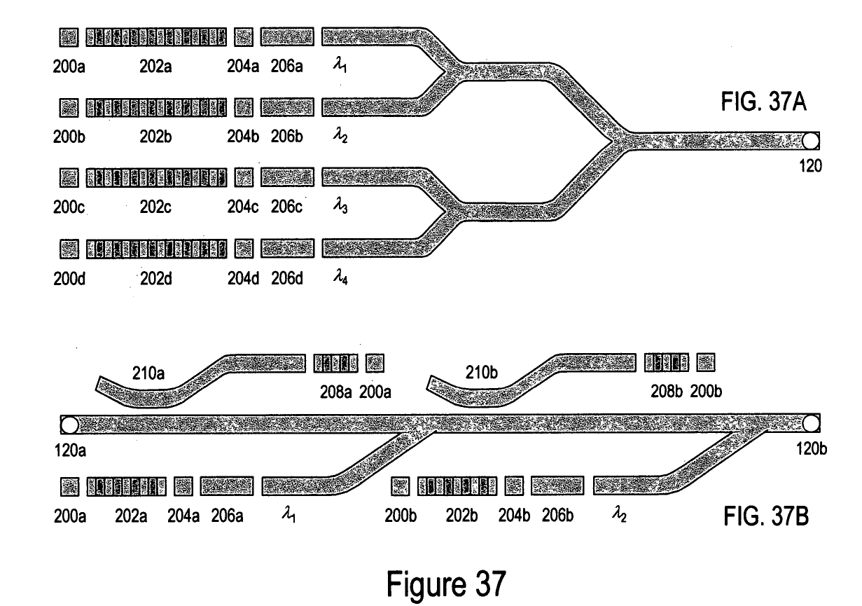

An exemplary embodiment of a wavelength division multiplexed (WDM) laser array is illustrated in FIG. 37(a). Vertical optical confinement is achieved via the effective cladding method and Lateral optical confinement is achieved via the resonant wavelength modulation technique. Each wavelength is generated by a PWVCL 202 with integrated EAM 204, amplifier 206 and power monitor 200. The modulated, amplified wavelengths are multiplexed in parallel onto the same waveguide via a Y-combiner. Alternatively, the multiplexing can occur in series, as in FIG. 37(b). Also in FIG. 37(b), a series array of waveguide taps 210, filters 208, and photo detectors 200 has been formed adjacent to the waveguide. In this way, the individual wavelengths can be detected and/or monitored. Optical taps 120 are formed at each end of the WDM waveguide. Alternatively, the output port can be formed via an etched or cleaved facet.

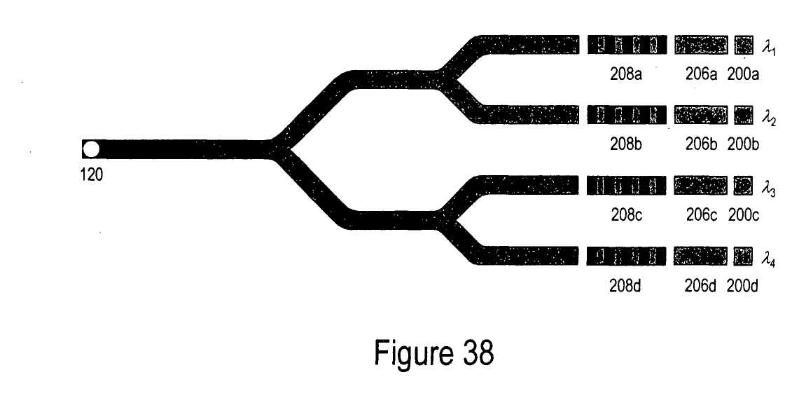

An exemplary embodiment of a wavelength division multiplexed (WDM) detector array is illustrated in FIG. 38. Vertical optical confinement is achieved via the effective cladding method and lateral optical confinement is achieved via the resonant wavelength modulation technique described as well as an optical tap 120 is formed at the input end of the WDM waveguide. Alternatively, the input port can be formed via an etched or cleaved facet. The WDM signal is divided onto separate waveguides via a series of Y-splitters. A WDM filter array 208 is formed in the waveguide array. An amplifier array 206 is formed in the waveguide adjacent to the filter array. A detector array 200 is formed in the waveguide adjacent to the amplifier array. Each wavelength is detected by a filtered 208, pre-amplified 206 photodetector 200.

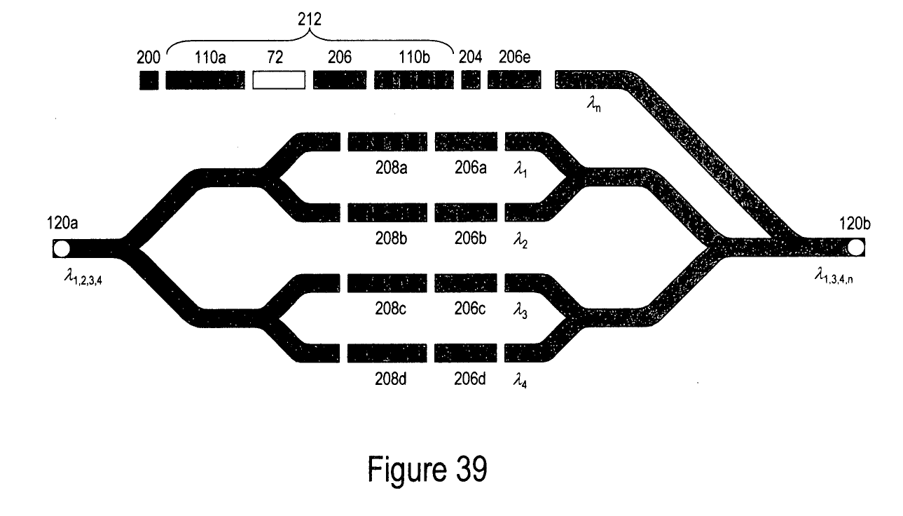

An exemplary embodiment of an optical add/drop multiplexer (OADM) is illustrated in FIG. 39. Vertical optical confinement is achieved via the effective cladding method, lateral optical confinement is achieved via the resonant wavelength modulation technique and an optical tap 120a is formed at the input end of the WDM waveguide, as described herein. Alternatively, the input port can be formed via an etched or cleaved facet. The WDM signal is split into separate waveguides via a series of Y-splitters, as described herein. A WDM filter array 208 is formed in the waveguide array. An amplifier array 206 is formed in the waveguide adjacent to the filter array. Beyond the amplifier array the waveguides are re-combined into a single waveguide via Y-combiners. An output tap is formed at the end of the output waveguide via optical tap 120b or etched or cleaved facet. A power monitored 200, tunable 214, externally modulated 204, amplified 206, single mode laser, is formed adjacent to the waveguide array, and coupled to the output waveguide via a Y-coupler.

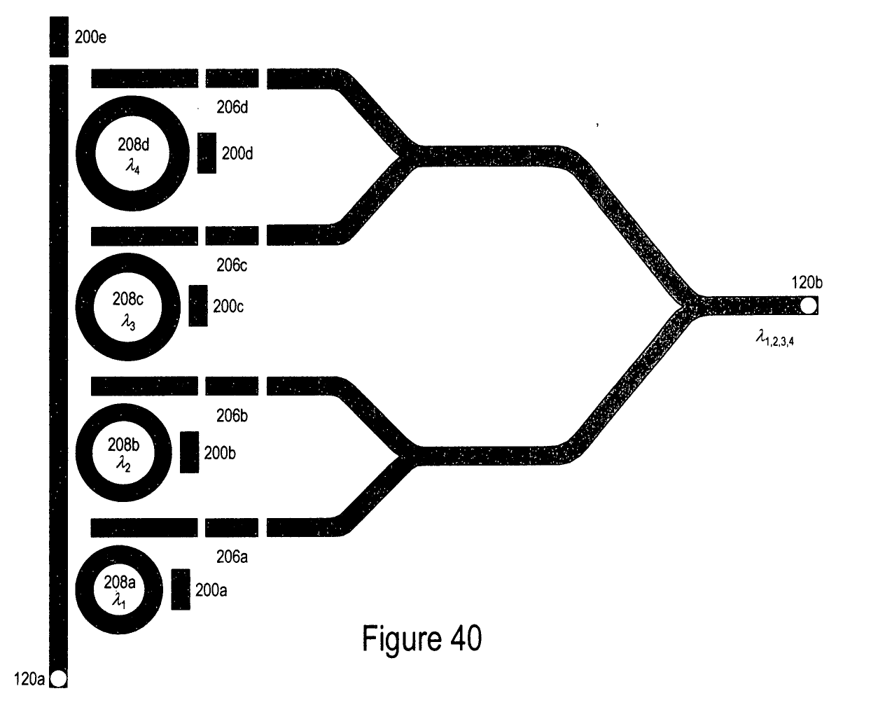

In operation, a WDM signal is injected into the waveguide at the input port and split among N waveguides, where N is the number of WDM channels. The WDM signal is split into its individual channels by the filter array 208 whereupon it is amplified 206 and recombined for output. In order to delete any single channel in the WDM signal, that wavelength's amplifier 206 is turned off or reverse biased to absorb the signal. In order to add a wavelength, the PWVCL 212 is tuned to the desired wavelength and it's modulated, amplified output is multiplexed onto the output waveguide. An exemplary embodiment of an optical dynamic equalizer is illustrated in FIG. 40. Vertical optical confinement is achieved via the effective cladding method, lateral optical confinement is achieved via the resonant wavelength modulation technique and an optical tap 120a is formed at the input end of the WDM waveguide, as described herein. Alternatively, the input port can be formed via an etched or cleaved facet. The WDM signal is split into separate waveguides via a series of resonant ring filters 208. A separate waveguide array is formed adjacent to the filter array. An amplifier array 206 is formed in the waveguide array. Beyond the amplifier array the waveguides are re-combined into a single waveguide. An output tap is formed at the end of the output waveguide via optical tap 120b or etched or cleaved facet. A photodetector array 200a, 200b, 200c and 200d is formed adjacent to the filter array. A power monitor photodetector 200e is formed at the end of the input waveguide.

In operation, a WDM signal is injected into the waveguide at the input port 120a. The wavelengths are tapped off one by one by the ring resonator filters and split among N waveguides, where N is the number of WDM channels. The optical strength of the individual channels is detected by the photodetector array 200a through 200d, while the optical strength of the WDM signal is detected by the power monitor photodetector 200e. The individual channels strength is compared to the average channel strength electronically, for example by an operational amplifier (not shown), whereupon it is amplified proportionately by the optical amplifier and recombined for output.

### Optical Pumping

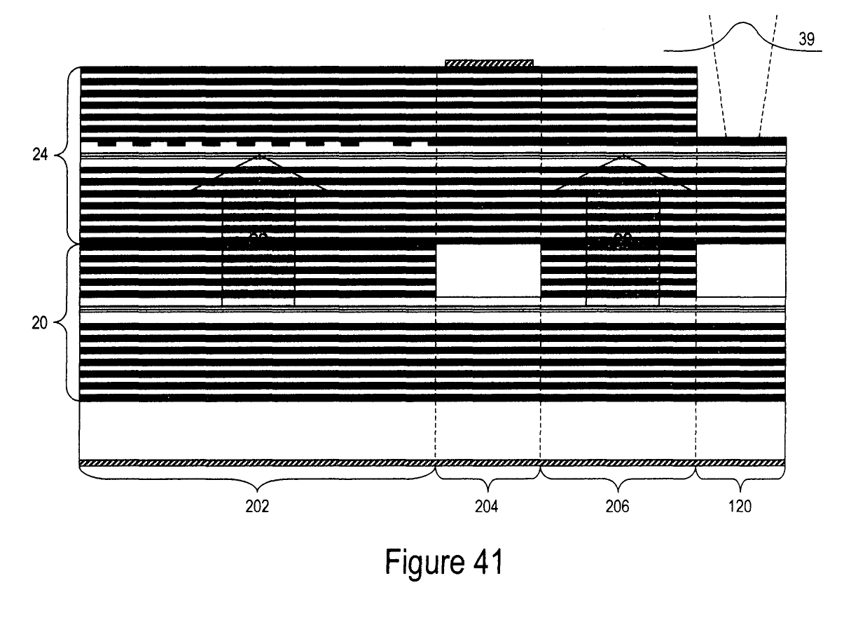

All of the embodiments discussed to this point have incorporated electrical pumping. Alternatively, the discrete or integrated devices can be optically pumped. An exemplary embodiment of an optically pumped, integrated PWVCL, EAM and amplifier is illustrated in FIG. 41. A pump VCL 20 is disposed on a substrate. In this embodiment, the pump lasers are grown separately. The pump VCL 20 provides optical power at the pump wavelength 22. Multiple pump VCLs can be defined via a mesa etch. Isolated electrodes (not shown) provide electrical pumping of the pump VCLs. One pump VCL is required for each integrated element that provides gain. In the present embodiment both the PWVCL 202 and amplifier 206 are optically pumped, while the EAM 204 is not. In addition to pumping from below, a pump laser can also be coupled in from the side of the PWVCL or amplifier, or an end of the PWVCL or amplifier waveguide.

The integrated PWVCL 202, EAM 204 and amplifier 206 are formed separately as described above. The substrate of the integrated structure is removed using etch methods and stop etch layers, as is known in the art. The pump laser 206 and integrated structure are joined using wafer bonding, as is known in the art. In operation, the majority of the pump power 22 is directed upwards at the integrated PWVCL/EAM/amplifier structure. The pump DFBSEL output beam 22 is significantly absorbed in the PWVCL 202 and amplifier 204 active areas creating electron-hole pairs, which provide gain at the second PWVCL wavelength.

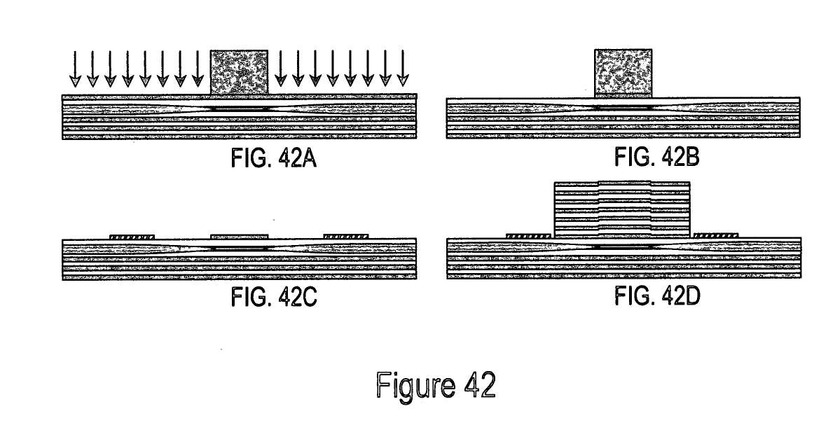

A method for fabrication of an effective index modulation structure is illustrated in FIGS. 42(a), 42(b), 42(c) and 42(d). Referring to FIG. 42(a), a SiNx layer of thickness equal to the lateral perturbation is disposed on the mirror plus cavity structure. An ion implant mask is disposed on the SiNx layer and patterned into the shape of a waveguide. Ion implantation is used to form a current constriction to force current into the waveguide. Referring to FIG. 42(b), an etch technique, such as wet chemical or dry plasma etching, is used to pattern the SiNx layer into the shape of the waveguide. Referring to FIG. 42(c), the implant and etch mask is removed, leaving the waveguide perturbation layer. Top electrodes are formed on either side of the waveguide perturbation layer. Referring to FIG. 42(d), the top dielectric mirror is disposed on the structure and patterned to expose the contacts.

The previous description of the disclosed embodiments is provided to enable any person skilled in the art to make or use the present invention. Various modifications to these embodiments will be readily apparent to those skilled in the art, and the generic principles defined herein can be applied to other embodiments without departing from the spirit or scope of the invention. For example, the present invention can be practiced with any of a variety of Group III-V or Group II-VI material systems that are designed to emit at any of a variety of wavelengths. It is therefore desired that the present embodiments be considered in all respects as illustrative and not restrictive, reference being made to the appended claims rather than the foregoing description to indicate the scope of the invention.

I claim:

1. A laser for optical confinement and feedback, comprising:
a pair of distributed Bragg reflector mirrors surrounding a cavity in a vertical direction (y);
a waveguide in the lateral direction (x); and
a distributed feedback grating in a longitudinal direction (z).

2. The laser of claim 1 wherein useful light is extracted using an optical tap, etched or cleaved facet.

3. The laser of claim 1 wherein lateral optical confinement is achieved using modulation from one of the following means gain/loss modulation, index modulation, effective index modulation, and/or resonant wavelength modulation.

4. A laser of claim 1 wherein said laser comprises a distributed feedback grating in the radial (r) direction rather than a waveguide in the lateral direction (x) and said distributed feedback grating in said longitudinal direction (z).

5. The laser of claim 4 in which useful light is extracted using an optical tap, etched or cleaved facet.

6. The laser of claim 4 wherein lateral optical confinement is achieved using modulation from one of the following means gain/loss modulation, index modulation, effective index modulation, and/or resonant wavelength modulation.

7. A device for optical confinement and feedback, comprising:
a pair of distributed Bragg reflector mirrors surrounding a cavity in the vertical (y) direction;
a waveguide in the lateral (x) direction; and
no optical confinement in the longitudinal (z) direction.

8. The device of claim 7 wherein useful light is extracted using an optical tap, etched or cleaved facet.

9. The device of claim 7 wherein said device is an active waveguide.

10. The device of claim 7 wherein the device is a combiner, splitter, or mixer.

11. The device of claim 7 wherein lateral optical confinement is achieved using modulation from one of the following means gain/loss modulation, index modulation, effective index modulation, and/or resonant wavelength modulation.

12. The device of claim 7 wherein the device is selected to be one of the following group a switch, a filter, a modulator, an amplifier, or a photodetector.

13. A photonic integrated circuit, comprising:
a pair of distributed Bragg reflector mirrors surrounding a cavity in a vertical (y) direction,
a waveguide in a lateral (x) direction, and
optical tap means for injecting or extracted light from said waveguide.

14. The photonic integrated circuit of claim 13 wherein component devices consist of one or more of the following: an active waveguide, a combiner, a splitter, a mixer, a switch, a passive waveguide, a filter, a modulator, an amplifier, a tuning section, a photodetector.

15. The photonic integrated circuit of claim 13 wherein component integration is provided by means outside of the plane of the active waveguide utilizing reflective or diffractive elements.
